(19) United States
(12) Patent Application Publication
(10) Pub. No.: US 2026/0060043 A1
(43) Pub. Date: Feb. 26, 2026

(54) WAFER AND/OR CHIP COMPRISING MEMORY CELL STRUCTURE AND METHOD FOR WAFER QUALITY ASSESSMENT

(71) Applicant: QUALCOMM Incorporated, San Diego, CA (US)

(72) Inventors: Woo Tag KANG, San Diego, CA (US); Mustafa BADAROGLU, San Diego, CA (US); Jihong CHOI, San Diego, CA (US); Zhongze WANG, San Diego, CA (US); Giridhar NALLAPATI, San Diego, CA (US); Periannan CHIDAMBARAM, San Diego, CA (US)

(21) Appl. No.: 19/309,489

(22) Filed: Aug. 25, 2025

Related U.S. Application Data
(60) Provisional application No. 63/687,218, filed on Aug. 26, 2024.

(51) Int. Cl. H01L 21/66; H01L 23/00; H01L 23/48; H01L 25/18; H10B 80/00; H10D 80/30

(52) U.S. Cl. CPC H01L 22/34; H01L 22/32; H01L 25/18; H10B 80/00; H10D 80/30; H01L 23/481; H01L 24/08; H01L 24/16; H01L 2224/08148; H01L 2224/16148; H01L 2225/06513; H01L 2225/06541

(57) ABSTRACT

A device comprising a substrate; and a stack of chips coupled to the substrate, wherein the stack of chips comprises: a logic chip; and a first memory chip coupled to the logic chip, wherein the first memory chip comprises a first die substrate; a first plurality of memory cells; and a first plurality of memory cell structures located along at least one edge of the first memory chip.

### CROSS-REFERENCE TO RELATED APPLICATION

This application claims priority to and the benefit of U.S. Provisional Application Ser. No. 63/687,218, filed in the United States Patent and Trademark Office on Aug. 26, 2024, the entire content of which is incorporated herein by reference as if fully set forth below in its entirety and for all applicable purposes.

### FIELD

Various features relate to packages with substrates and semiconductor chips.

### BACKGROUND

A package may include a substrate and semiconductor chips. These components are coupled together to provide a package that may perform various electrical functions. There is an ongoing need to provide better performing packages, including packages with improved thermal performances and/or electrical performances. Moreover, there is also an ongoing need to reduce the overall size of the packages.

### SUMMARY

Various features relate to packages with substrates and semiconductor chips.

One example provides a device comprising a substrate; and a stack of chips coupled to the substrate, wherein the stack of chips comprises: a logic chip; and a first memory chip coupled to the logic chip, wherein the first memory chip comprises a first die substrate; a first plurality of memory cells; and a first plurality of memory cell structures located along at least one edge of the first memory chip.

Another example provides a chip comprising: a die substrate; a plurality of memory cells; and a plurality of memory cell structures located along at least one edge of the chip.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary block diagram of a logic chip.

FIG. 2 illustrates an exemplary diagram of a stack of chips.

FIG. 3 illustrates an exemplary cross sectional profile view of a package that includes a chip and a stack of chips.

FIG. 4 illustrates an exemplary diagram of a wafer that can be singulated into individual chips.

FIG. 5 illustrates an exemplary plan view of a wafer that includes uncut dies.

FIG. 6 illustrates an exemplary plan view of a wafer that includes uncut dies and a plurality of memory cell structures.

FIG. 7 illustrates an exemplary view of a plurality of chips that include a plurality of memory cell structures.

FIG. 8 illustrates an exemplary block diagram of a memory cell structure.

FIG. 9 illustrates an exemplary cross sectional profile view of a semiconductor chip that includes a memory cell structure.

FIG. 10 illustrates an exemplary cross sectional profile view of a chip coupled another chip through back to back hybrid bonding.

FIG. 11 illustrates an exemplary cross sectional profile view of a chip coupled another chip through front to front hybrid bonding.

FIG. 12 illustrates an exemplary cross sectional profile view of a chip coupled another chip through back to front solder interconnect coupling.

FIG. 13 illustrates an exemplary flow chart of a method for fabricating and testing a stack of wafers.

FIGS. 14A-14B illustrate an exemplary sequence for fabricating and testing a stack of chips.

FIG. 15 illustrates an exemplary flow chart of a method for fabricating and testing a stack of chips.

FIGS. 16A-16B illustrate an exemplary sequence for fabricating a package comprising a chip and a stack of chips.

FIG. 17 illustrates an exemplary flow chart of a method for fabricating a package comprising a chip and a stack of chips.

FIG. 18 illustrates a block diagram showing an exemplary wireless communications system in which a configuration of the disclosure may be advantageously employed.

FIG. 19 illustrates a block diagram illustrating a design workstation used for circuit, layout, and logic design of a semiconductor component, such as the disclosed dynamic random-access memory (DRAM) cell array micro-structure.

FIG. 20 illustrates various electronic devices that may integrate a die, an electronic circuit, a semiconductor chip, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device comprising a substrate; and a stack of chips coupled to the substrate, wherein the stack of chips comprises: a logic chip; and a first memory chip coupled to the logic chip, wherein the first memory chip comprises a first die substrate; a first plurality of memory cells; and a first plurality of memory cell structures located along at least one edge of the first memory chip. The presence of the first plurality of memory cell structures can help assess the quality of the wafer before wafer to wafer bonding. This helps improve the yield of the stack of chips.

Memory is a vital component for processing systems, such as wireless communications devices. For example, a cell phone may integrate memory as part of an application processor, such as a system-on-chip (SoC) including a central processing unit (CPU), a graphics processing unit (GPU), and a neural processing unit (NPU). Successful operation of some applications depends on the availability of a high-capacity and low-latency memory solution for scalability of processor workload. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). State of the art three-dimensional (3D) stacked memories composed of high-bandwidth DRAM provide advantages in performance and power for memory-demanding workloads. Single-stacked DRAM yield is a significant factor in these 3D stacked memories. For example, a single DRAM yield of 97% is reduced to a stacked yield of less than 78% in an integration scheme that utilizes low-cost wafer-to-wafer stacking of eight wafers. Due to this limited yield, DRAM vendors prefer slow and costly die-to-die stacking for implementing HBM solutions.

Three-dimensional (3D) memory stacking involves a base logic chip that supports stacking of memory chips (e.g., DRAM chips) on the base logic chips. Successful fabrication of a stacked wide input/output (IO) 3D DRAM on a base SoC logic chip is dependent on the accuracy of the DRAM wafer yield projection. In short, accuracy of the DRAM wafer yield projection is key for the desired 3D DRAM stacking yield before DRAM wafer-to-wafer bonding is performed. Ideally, a full DRAM function test may be performed on all the DRAM chip on a DRAM wafer. Unfortunately, performing a DRAM wafer function test is particularly challenging because most of the DRAM periphery circuits are moved into the base SoC logic chip. Additionally, the DRAM function test is complicated by the vast number of DRAM IO pins (e.g., 1000˜20000 pins) on the DRAM wafer level. Furthermore, probe marks on DRAM test pads in case of DRAM wafer function tests can also negatively impact the DRAM wafer-to-wafer bonding process quality/yield.

Therefore, DRAM wafer functional testing is skipped before the DRAM wafer-to-wafer bonding process, which limits DRAM testing to a fabrication monitoring test (e.g., wafer acceptance test (WAT) using fabrication monitoring parameters on the scribe line). As a result, the DRAM wafer quality assessment is limited to the standard WAT parameter test results. Unfortunately, the fabrication monitoring parameter test results provide an inaccurate representation of the overall combined DRAM process effect for DRAM wafer yield projection. As a result, the correlation between WAT parameter test results and DRAM wafer yield is poor. Therefore, an extremely low DRAM wafer yield can be included on the multi-DRAM wafer-to-wafer bonding process. This low DRAM wafer yield significantly reduces 3D DRAM yield. Therefore, a more accurate DRAM wafer yield projection method on the wafer scribe line is desired.

Various aspects of the present disclosure are directed to DRAM cell array micro-structures. In some implementations, several different DRAM cell array micro-structures represent DRAM process effects and align with (or correlate with) the actual DRAM functional wafer yield. Some implementations resolve the noted issues by implementing multiple small DRAM cell array micro-structures in horizontal/vertical directions of the wafer scribe line. These DRAM cell array micro-structures can project more robust DRAM cell array yield on the wafer by overcoming the noted deficiencies of the DRAM wafer quality assessment that is based on standard WAT test structures.

Exemplary Package Comprising a Stack of Chips with Memory Cell Structures

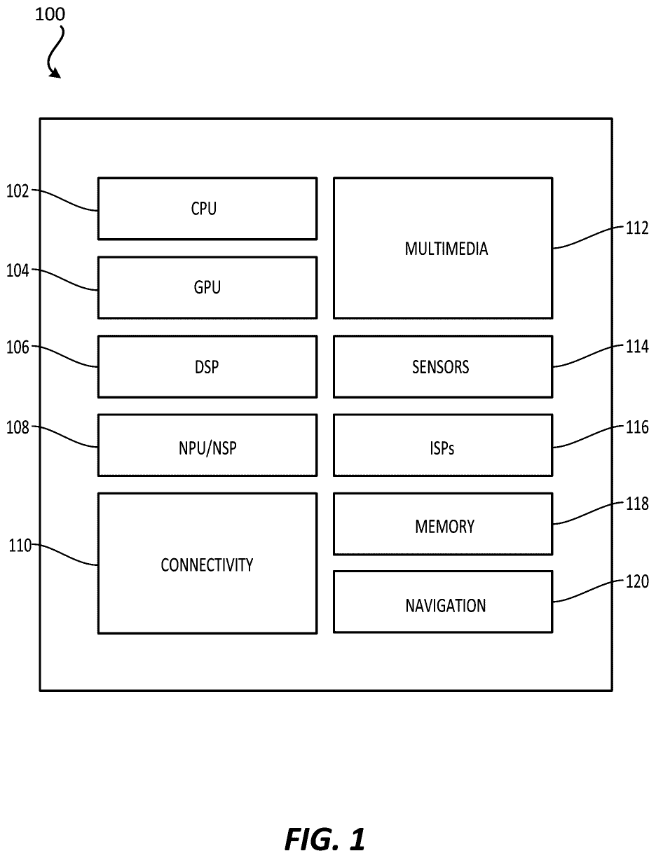

FIG. 1 illustrates an example implementation of a host system-on-chip (SoC) 100, which includes a memory cell structure placement and test for improved wafer quality assessment of a three-dimensional (3D) stacked memory, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU/NSP 108 may be based on an ARM instruction set.

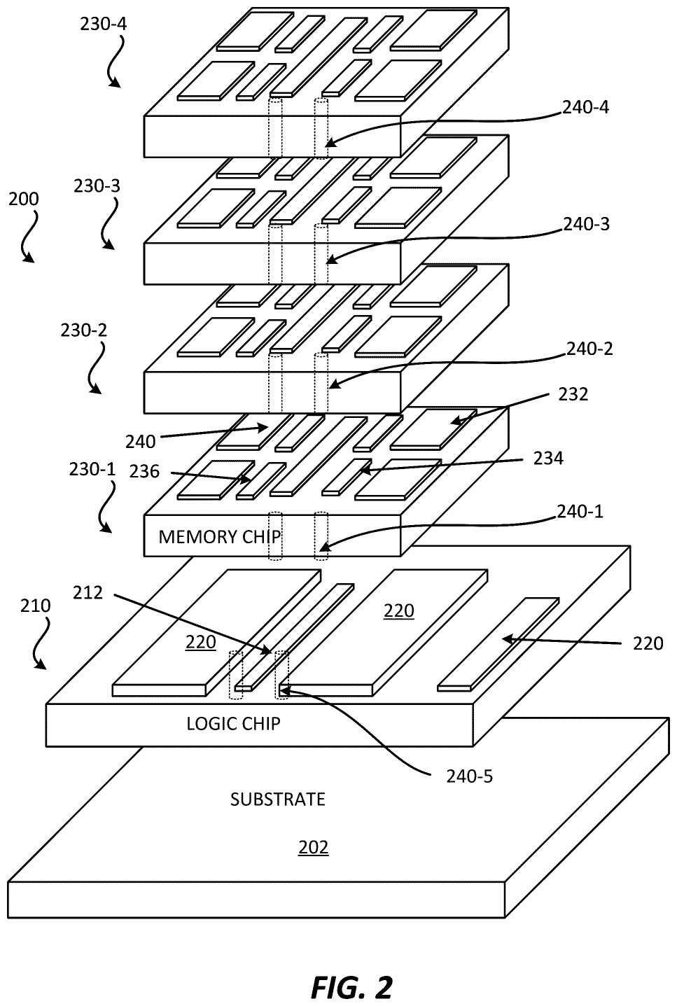

FIG. 2 is an example of a block diagram illustrating a stack of chips 200. The stack of chips 200 may be a high-bandwidth three-dimensional (3D) stacked memory chip fabricated from verified wafers using a memory cell array structure placement and test for wafer quality assessment, according to various aspects of the present disclosure. As shown in FIG. 2, the stack of chips 200 includes a base chip 210 (e.g., a first chip) that is supported by and/or coupled to a substrate 202 (e.g., package substrate, interposer). The base chip 210 may be a logic chip. In various aspects of the present disclosure, the base chip 210 supports stacking of memory chips 230 (e.g., dynamic random-access memory (DRAM) chips) on the base chip 210. The number of memory dies stacked on the base chips 210 varies in different implementations. In this example, four (4) memory chips 230 (230-1, 230-2, 230-3, 230-4) are arranged using a back-to-face stacking of DRAM chips on the base chip 210. In another implementation, the base chip 210 supports a stack of twelve (12) DRAM chip.

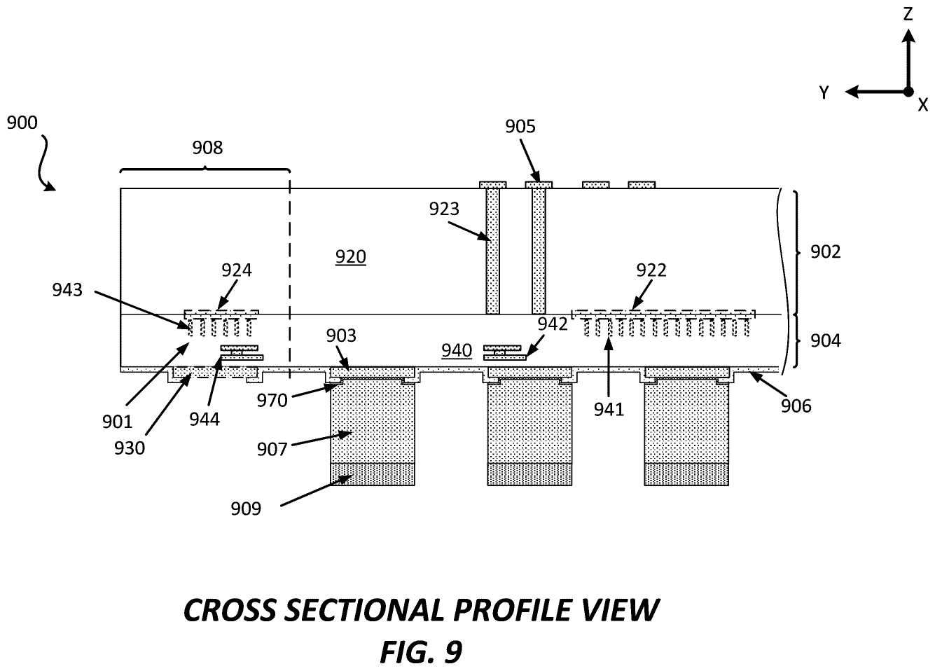

In various aspects of the present disclosure, the memory chips 230 include memory blocks (e.g., memory banks (BANK)) and an input/output (IO) block that utilize signal through silicon vias (TSVs) 240 (e.g., 240-1, 240-2, 240-3, 240-4) extending through the memory chips 230 (e.g., second chip) and landing on the base chip 210. The TSVs 240-5 may extend through the base chip 210. As shown in FIG. 2, the TSVs 240 provide signal transmission between the memory chips 230 and a physical IO module (PHY) 220 of the base chip 210. In this example, a processing unit (PU) (e.g., a neural signal processor (NSP)) may be implemented on the base chip 210 in combination with the PHY 220, including a PHY 220 to a system-on-chip (e.g., SoC 100). Additionally, the high-stack of chips 200 includes DRAM power TSVs (not shown) between the memory blocks and the substrate 202. It is noted that the TSVs 240 is a conceptual representation of TSVs. A TSV may extend through the silicon portion of the memory chip. Each memory chip from the memory chips 230 may have its own TSVs 240. FIG. 2 illustrates two (2) TSVs 240 for each memory chip to avoid obscuring the view of the drawing; however, one of skill in the art can readily recognize that there can be more TSVs in the stack of memory chips 230 and/or TSVs at other locations within the stack of memory chips 230. A more detailed example of TSVs in a chip is illustrated and described in at least FIG. 9.

A memory chip can includes bus interconnect unit, a processing unit, a physical layer unit, a data correction unit, a test unit. A processing unit may be a unit of the chip configured to process input and/or output data. A bus interconnect unit may be a unit of the chip configured to manage where and/or how data travels between different units in the chip. A physical layer unit may be a unit of the chip configured to manage how data (e.g., input/output signals) enters and/or leaves the chip. A memory unit or a memory block may be a unit of the chip configured to store data. A data correction unit may be a unit of the chip configured to check data that is stored and/or retrieved from the memory unit or memory block. The test unit is a unit of the chip that is configured to check that the memory units work probably.

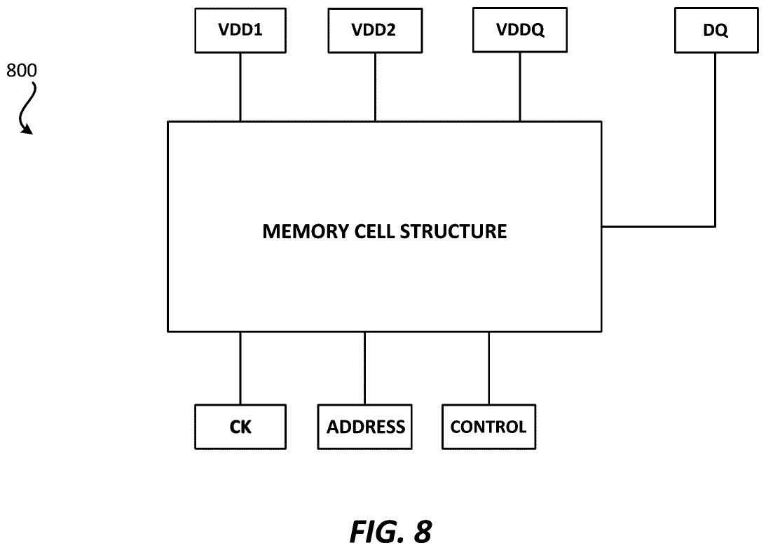

As will be further described below, one or more of the memory chips 230 may include a plurality of memory cell structures. The plurality of memory cell structures may be used to properly test and assess a the quality of wafer that includes memory circuits. A memory cell structure is further described below in at least FIGS. 8 and 9.

The manufacture of electrical circuits on semiconductor wafers (e.g., DRAM wafers) incorporates circuit testing at several stages of the fabrication process. A final test at the wafer level is usually the most important as it affects the yield of the process as well as the additional cost of further processing for defective products. The usual method of wafer testing utilizes probes that contact the metal surface pads of a wafer. These surface pads are connected to the semiconductor circuits. The probes in turn are connected to highly sophisticated test circuitry that provides electrical signals to the circuits and analyzes their response. This process is important for testing memory, such as the stack of chips 200 of FIG. 2.

In this implementation, the base chip 210 supports 3D stacking of the memory chips 230 (e.g., DRAM chips) on the base chip 210. Successful fabrication of the stack of chips 200 is dependent on the accuracy of the DRAM wafer yield projection. In short, accuracy of the DRAM wafer yield projection is key for the desired 3D DRAM stacking yield before DRAM wafer-to-wafer bonding is performed. Ideally, a full DRAM function test may be performed on all the DRAM dies on a DRAM wafer. Unfortunately, performing a DRAM wafer function test is particularly challenging because most of the DRAM periphery circuits are moved into the base SoC logic die. Therefore, DRAM wafer functional testing is skipped before the DRAM wafer-to-wafer bonding process, which limits DRAM testing to fabrication monitoring test (e.g., wafer acceptance test (WAT) using fabrication monitoring parameters on the scribe line).

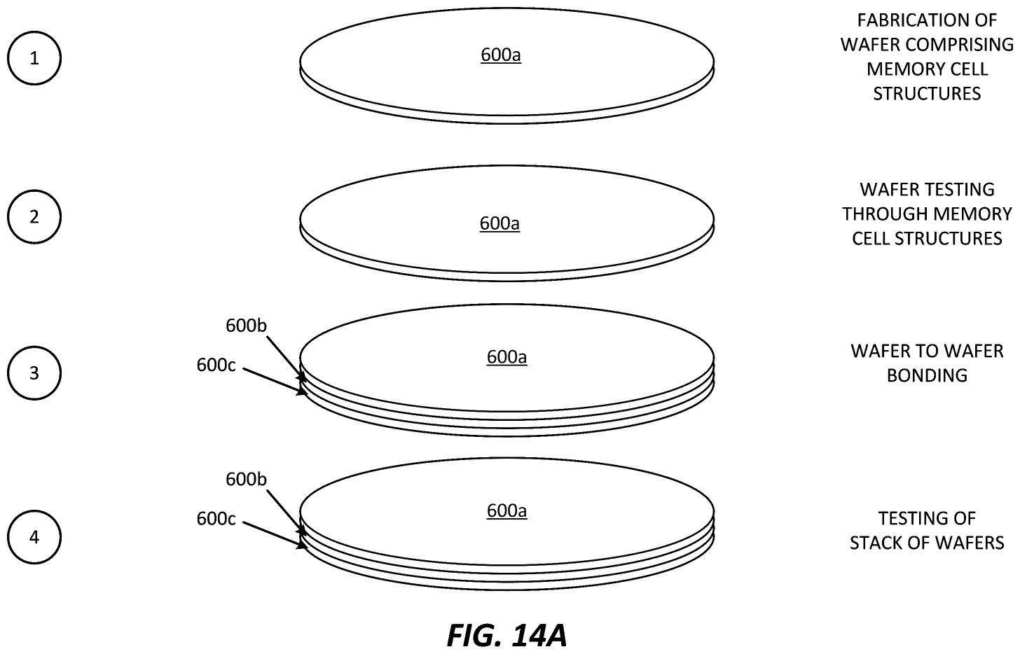

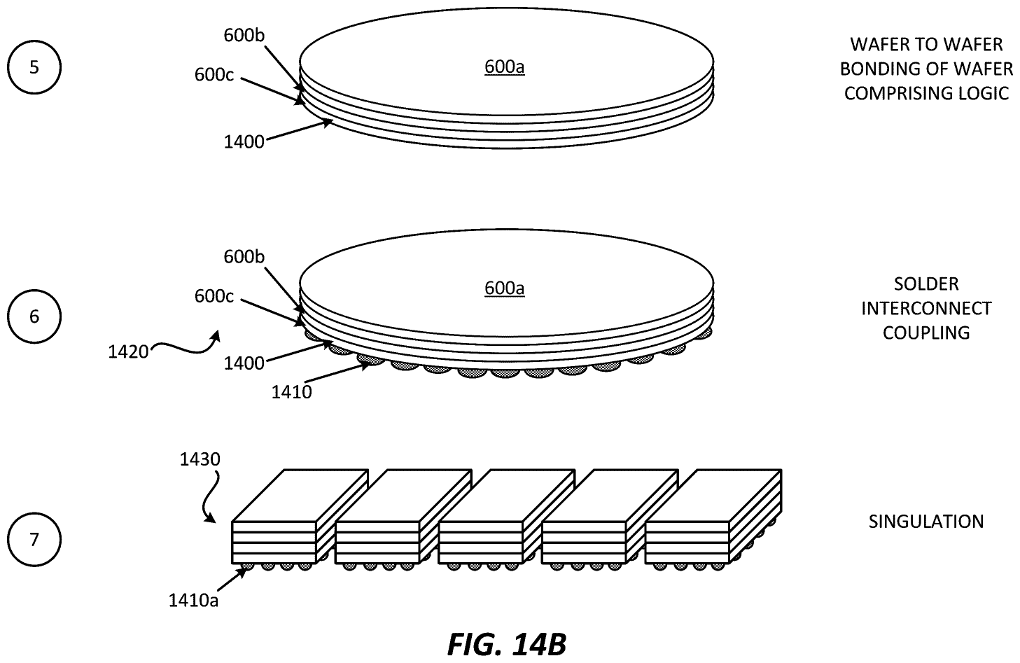

In practice, DRAM wafer quality assessment is limited to the standard WAT parameter test results performed by the foundry (fab). Unfortunately, the fabrication monitoring parameter test results provide an inaccurate representation of the overall combined DRAM process effects for DRAM wafer yield projection. As a result, the correlation between WAT parameter test results and DRAM wafer yield is poor. Therefore, an extremely low DRAM wafer yield can be included in a multi-DRAM wafer-to-wafer bonding process. This low DRAM wafer yield significantly reduces 3D DRAM yield. A DRAM wafer yield projection method on the wafer scribe line for improved wafer assessment test prior to formation of the high-bandwidth 3D memory chip is shown, for example, in FIGS. 14A-14B.

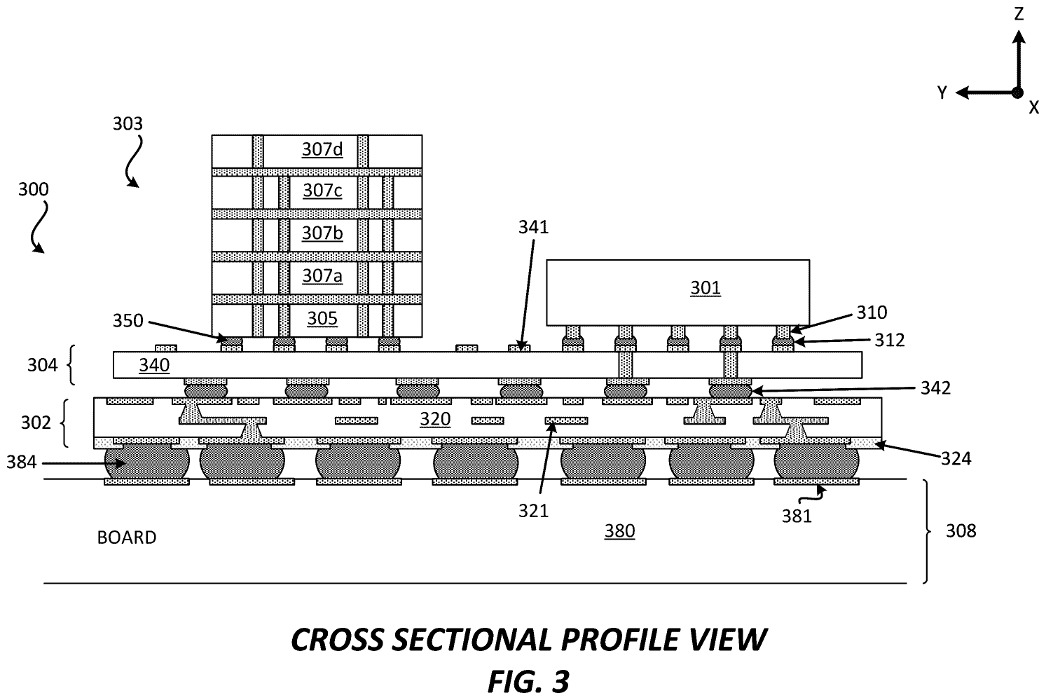

FIG. 3 illustrates a cross sectional profile view of a package 300 that includes a stack of chips. The package 300 may be coupled to a board 308 through a plurality of solder interconnects 384. The board 308 may be a printed circuit board (PCB). The board 308 may include at least one board dielectric layer 380 and a plurality of board interconnects 381. The package 300 includes a chip 301, a substrate 302, a substrate 304 and a stack of chips 303.

The substrate 302 may be a laminated substrate. The substrate 302 includes at least one dielectric layer 320, a plurality of interconnects 321 and a solder resist layer 324. In some implementations, the at least one dielectric layer 320 can include prepreg. However, different implementations may use different materials for the at least one dielectric layer 320. In some implementations, the substrate 302 can be a coreless substrate, such as an embedded trace substrate. In some implementations, the substrate 302 may be a core substrate. The substrate 304 may be an interposer. The substrate 304 may include at least one dielectric layer 340 and a plurality of interconnects 341. The at least one dielectric layer 340 can include silicon or glass. However, different implementations may use different materials for the at least one dielectric layer 340. The substrate 304 may be coupled to the substrate 302 through a plurality of solder interconnects 342. The plurality of solder interconnects 342 may be coupled to and touch the plurality of interconnects 321 and the plurality of interconnects 341. The substrate 302 may be coupled to the board 308 through a plurality of solder interconnects 384. The plurality of solder interconnects 384 may be coupled to and touch the plurality of the plurality of interconnects 321 and the plurality of board interconnects 381.

The chip 301 may be coupled to the substrate 304 through a plurality of pillar interconnects 310 and a plurality of solder interconnects 312. The plurality of solder interconnects 312 may be coupled to and touch the plurality of pillar interconnects 310 and the plurality of interconnects 341. In some implementations, the plurality of pillar interconnects 310 may be optional. In some implementations, the chip 301 may include a logic chip and/or a logic die. The chip 301 may include an application processor (AP), a central processing unit (CPU), a graphical processing unit (GPU) and/or neural processing unit (NPU). The chip 301 can be implemented as a system on chip (SoC).

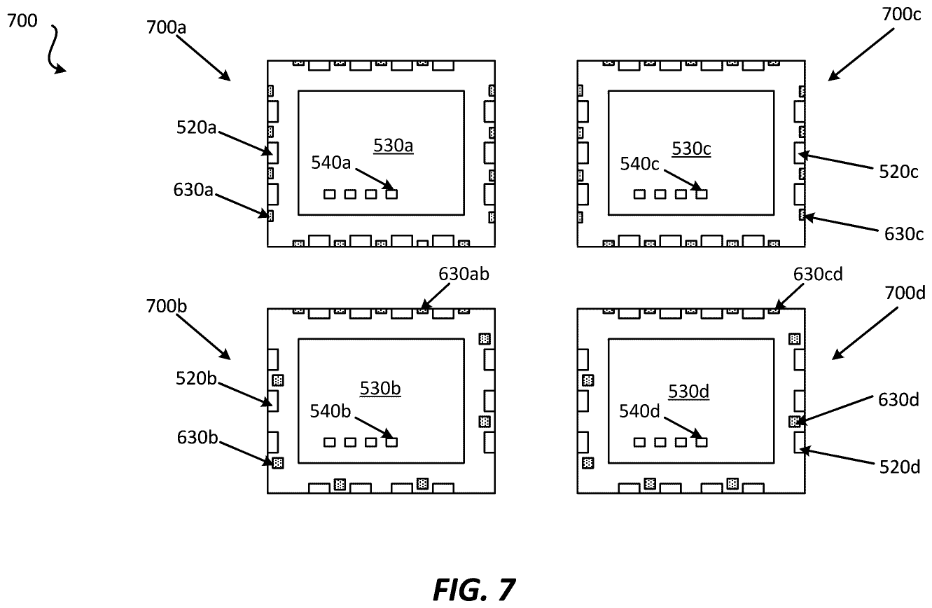

The stack of chips 303 may be coupled to the substrate 304 through a plurality of solder interconnects 350. The plurality of solder interconnects 350 may be coupled to the plurality of interconnects 341 of the substrate 304. The stack of chips 303 may be laterally adjacent and/or laterally next to the chip 301. The stack of chips 303 may include a chip 305, a chip 307a, a chip 307b, a chip 307c and a chip 307d. The chip 305 may be a logic chip. The chip 307a may be a memory chip. The chip 307b may be a memory chip. The chip 307c may be a memory chip. The chip 307d may be a memory chip. As will further described below, the chip 305, the chip 307a, the chip 307b, the chip 307c and/or the chip 307d may include a plurality of through substrate vias (TSVs). The plurality of through substrate vias (TSVs) can be a plurality of through silicon vias. A via can be a via interconnect (e.g., through substrate via interconnects, through silicon via interconnects). As will be further described below, one or more of the chips (e.g., 307a, 307b, 307c, 307d) may include a plurality of memory cell structures. The plurality of memory cell structures may be used to properly test and assess a the quality of wafer that includes memory circuits. A memory cell structure is further described below in at least FIGS. 7, 8 and 9. In some implementations, the chip 307a, the chip 307b, the chip 307c and/or the chip 307d may represent the chip 700a, the chip 700b, the chip 700c and/or the chip 700d, as described below in at least FIG. 7.

The chip 305 may include a central processing unit (CPU), a graphical processing unit (GPU) and/or neural processing unit (NPU), which allows the processing units to be located very close to the memory chips, resulting in faster processing and compute of data. A memory chip may include Dynamic Random Access Memory (DRAM). Different implementations may include a memory chip with different types of memory and/or different memory sizes. The stack of chips 303 may include stacks of DRAM or any type and/or combination of memory types. The stack of chips 303 may represent a high bandwidth memory (HBM). As will be further described below, the chip 305, the chip 307a, the chip 307b, the chip 307c and the chip 307d are arranged, configured and/or coupled in such a way as to improve the performance of data retrieval and storage in the stack of chips.

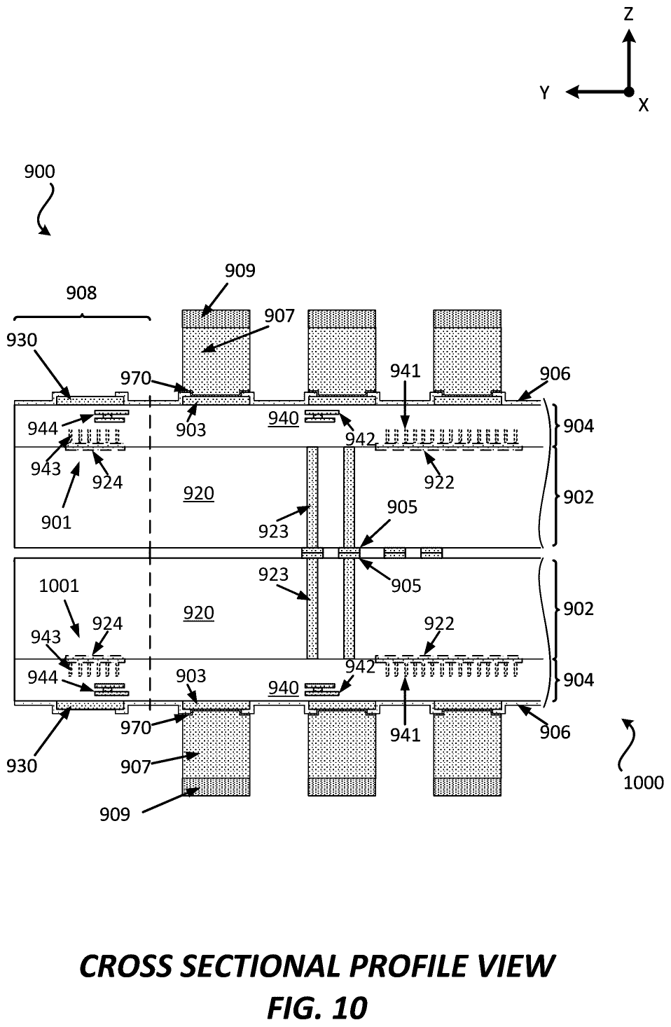

The chip 307a may be coupled to the chip 305 through hybrid bonding. The chip 307b may be coupled to the chip 307a through hybrid bonding. The chip 307c may be coupled to the chip 307b through hybrid bonding. The chip 307d may be coupled to the chip 307c through hybrid bonding. A chip may be coupled to another chip through front side to front side coupling, front side to back side coupling or back side to back side coupling. Examples of front side to front side coupling, front side to back side coupling and back side to back side coupling of chips are further described in details below in at least FIGS. 10-12.

The stack of chips 303 may be electrically coupled to the chip 301 through an electrical path that includes (i) a solder interconnect from the plurality of solder interconnects 350, (ii) at least one interconnect from the plurality of interconnects 341, (iii) a solder interconnect from the plurality of solder interconnects 312 and/or (iv) a pillar interconnect from the plurality of pillar interconnects 310.

In some implementations, the substrate 304 may be optional. In such instances, the chip 301 may be coupled to the substrate 302 through the plurality of pillar interconnects 310 and the plurality of solder interconnects 312. The plurality of solder interconnects 312 may be coupled to and touch the plurality of pillar interconnects 310 and the plurality of interconnects 321 of the substrate 302. Moreover, when the substrate 304 is optional, the stack of chips 303 may be coupled to the substrate 302 through the plurality of solder interconnects 350, such that the plurality of solder interconnects 350 are coupled to and touch the plurality of interconnects 321 of the substrate 302. When the substrate 304 is optional, the stack of chips 303 may be electrically coupled to the chip 301 through an electrical path that includes (i) a solder interconnect from the plurality of solder interconnects 350, (ii) at least one interconnect from the plurality of interconnects 321, (iii) a solder interconnect from the plurality of solder interconnects 312 and/or (iv) a pillar interconnect from the plurality of pillar interconnects 310.

In some implementations, the chip 301 may be a first chiplet based on a first technology node and the stack of chips 303 may include at least one chiplet based on a second technology node, that is different from the first technology node. For example, the chip 305, the chip 307a, the chip 307b, the chip 307c and/or the chip 307d may be chiplets based on one or more technology nodes that is/are different the technology node used to fabricate the chip 301. In some implementations, the chip 305 may be a first chiplet based on a first technology node and the chip 307a may be a second chiplet based on a second technology node, that is different from the first technology node. In some implementations, the chip 307a, the chip 307b, the chip 307c, the chip 307c and/or the chip 307d are chiplets based on the same technology node. The meaning of a technology node is further described below.

Although one stack of chips is shown, a package may include two or more stacks of chips. The stack of chips may be similar to each other. The stack of chips may have different number of chips. Similarly, two or more chips may be coupled to the substrate 302 or the substrate 304.

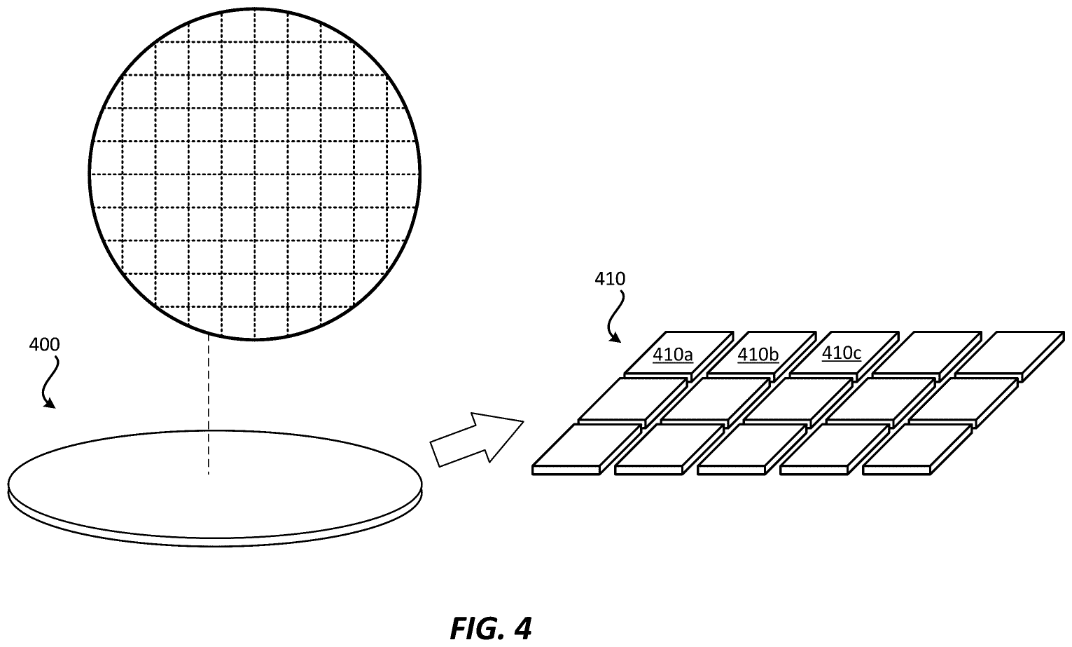

FIG. 4 illustrates a wafer 400 that includes a plurality of uncut dies and/or uncut chips. After singulation of the wafer 400, a plurality of chips 410 may be fabricated, including a chip 410a, a chip 410b, and a chip 410c. The plurality of chips 410 may include memory chips that have memory cell structures.

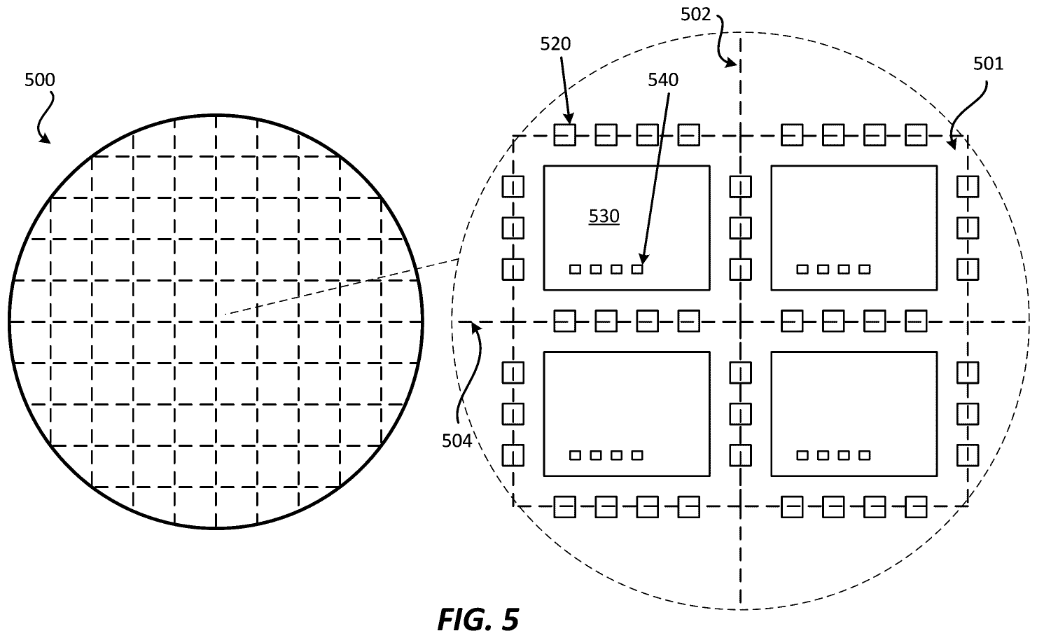

FIG. 5 illustrates an example of a wafer 500 that includes a plurality of uncut dies 501 (e.g., uncut chips). The plurality of uncut dies 501 may be defined by a plurality of scribe lines 502 and a plurality of scribe lines 504. The plurality of scribe lines 502 and the plurality of scribe lines 504 of the wafer 500 are regions of the wafer 500 that are cut and/or singulated (e.g., through a saw) to form a plurality of chips (e.g., 410). Each uncut die from the plurality of uncut dies 501 may include a memory portion 530, a plurality of pad interconnects 540 and a plurality of pad interconnects 520. The plurality of pad interconnects 540 may be electrically coupled to the memory portion 530. The plurality of pad interconnects 520 may be located in and/or along the plurality of scribe lines 502 and/or the plurality of scribe lines 504. The plurality of pad interconnects 520 may be a plurality of test pad interconnects, which are used to test each uncut die on the wafer 500. Each pad interconnect from the plurality of pad interconnects 520 may be used to test a particular uncut die of the wafer (e.g., test a memory portion 530 of a particular uncut die).

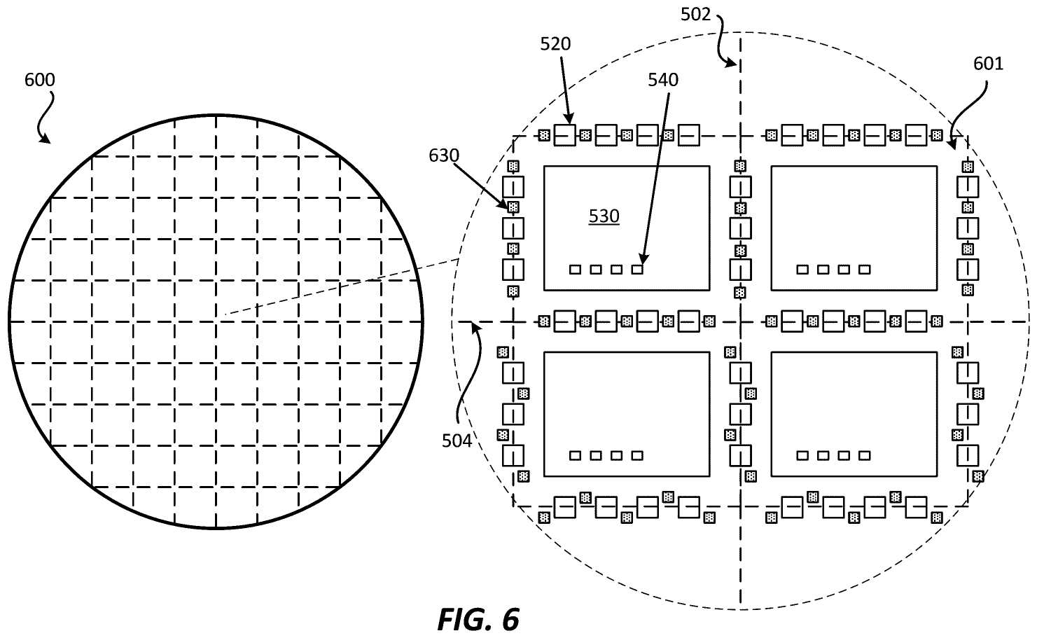

FIG. 6 illustrates an example of a wafer 600 that includes a plurality of uncut dies 601 (e.g., uncut chips). The plurality of uncut dies 601 may be defined by a plurality of scribe lines 502 and a plurality of scribe lines 504. The plurality of scribe lines 502 and the plurality of scribe lines 504 of the wafer 600 are regions of the wafer 600 that are cut and/or singulated (e.g., through a saw) to form a plurality of chips (e.g., 410). Each uncut die from the plurality of uncut dies 601 may include a memory portion 530, a plurality of pad interconnects 540, a plurality of pad interconnects 520 and a plurality of memory cell structures 630. The plurality of pad interconnects 540 may be electrically coupled to the memory portion 530. The plurality of pad interconnects 520 may be located in and/or along the plurality of scribe lines 502 and/or the plurality of scribe lines 504. The plurality of pad interconnects 520 may be a plurality of test pad interconnects, which are used to test each uncut die on the wafer 600. A pad interconnect from the plurality of pad interconnects 520 may be used to test a particular uncut die of the wafer (e.g., test a memory portion 530 of a particular uncut die). A pad interconnect from the plurality of pad interconnects 520 may be used to test a memory cell structure from the plurality of memory cell structures 630.

The plurality of memory cell structures 630 may be located in and/or along the plurality of scribe lines 502 and/or the plurality of scribe lines 504. In some implementations, the plurality of memory cell structures 630 may be located near and/or adjacent to the plurality of scribe lines 502 and/or the plurality of scribe lines 504. The plurality of memory cell structures 630 may include memory cells and/or logic cells. The plurality of memory cell structures 630 may be similar to the memory portion 530. One possible difference between the plurality of memory cell structures 630 and the memory portion 530, is that after singulation and individual chip are formed, the plurality of memory cell structures 630 may no longer be operational. The plurality of memory cell structures 630 may be used to assess the quality of the wafer before the wafer is bonded to another wafer. If a high percentage of the plurality of memory cell structures 630 of the wafer 600 are deemed to be defective, that particular wafer may be discarded since the expected yield of a stack of chips from that wafer will low, and it may not be worth it or cost effective to use that particular wafer. Thus, by inspecting and testing the plurality of memory cell structures 630 before wafer to wafer bonding and singulation, we can avoid unnecessary fabrication steps in the fabrication of a stack of chips that may ultimately be discarded anyways.

The plurality of memory cell structures 630 may include different memory capacity. For example, a first memory cell structure may include a first memory capacity, a second memory cell structure may include a second memory capacity that is different from the first memory capacity, and a third memory cell structure may include a third memory capacity that is different from the first memory capacity and the second memory capacity. Similarly, the plurality of memory cell structures 630 may include different memory densities. For example, a first memory cell structure may include a first memory density, a second memory cell structure may include a second memory density that is different from the first memory density, and a third memory cell structure may include a third memory density that is different from the first memory density and the second memory density. Examples of memory capacities and/or densities include 2K, 4K, 8K, 16K and/or 32K (bits).

FIG. 7 illustrates a plurality of chips 700. The plurality of chips 700 include a chip 700a, a chip 700b, a chip 700c and a chip 700d. The plurality of chips 700 may be a plurality of memory chips. The plurality of chips 700 may be formed by singulating the wafer 600 along the plurality of scribe lines 502 and the plurality of scribe lines 504.

The chip 700a includes a memory portion 530a, a plurality of pad interconnects 540a, a plurality of pad interconnects 520a, a plurality of memory cell structures 630a. The plurality of pad interconnects 520a and the plurality of memory cell structures 630a may be located along one or more edges (e.g., first edge, second edge, third edge, fourth edge) of the chip 700a. The plurality of pad interconnects 520a may be a plurality of partial pad interconnects, since portions of the pad interconnects may have been removed and/or destroyed during singulation. Some of the memory cell structures from the plurality of memory cell structures 630a may be a plurality of partial memory cell structures, since portions of the memory cell structures may have been removed and/or destroyed during singulation. The plurality of memory cell structures may be destroyed without affecting the performance of the chip 700a, since the plurality of memory cell structures 630a is not designed to be operational and/or functioning during the operation of the chip 700a. Moreover, the plurality of memory cell structures 630a may not be electrically coupled to the memory portion 530a. The plurality of memory cell structures 630a may include memory cell structures with different memory capacity and/or memory density.

The chip 700b includes a memory portion 530b, a plurality of pad interconnects 540b, a plurality of pad interconnects 520b, a plurality of memory cell structures 630b. The plurality of pad interconnects 520b and the plurality of memory cell structures 630b may be located along one or more edges (e.g., first edge, second edge, third edge, fourth edge) of the chip 700b. The plurality of pad interconnects 520b may be a plurality of partial pad interconnects, since portions of the pad interconnects may have been removed and/or destroyed during singulation. Some of the memory cell structures from the plurality of memory cell structures 630b may be a plurality of partial memory cell structures, since portions of some of the memory cell structures may have been removed and/or destroyed during singulation. For example, the plurality of memory cell structures 630ab are at least partially destroyed. The plurality of memory cell structures may be destroyed without affecting the performance of the chip 700b, since the plurality of memory cell structures 630b is not designed to be operational and/or functioning during the operation of the chip 700b. Moreover, the plurality of memory cell structures 630b may not be electrically coupled to the memory portion 530b. The plurality of memory cell structures 630b and/or the plurality of cell structures 630ab may include memory cell structures with different memory capacity and/or memory density.

The chip 700c includes a memory portion 530c, a plurality of pad interconnects 540c, a plurality of pad interconnects 520c, a plurality of memory cell structures 630c. The plurality of pad interconnects 520c and the plurality of memory cell structures 630c may be located along one or more edges (e.g., first edge, second edge, third edge, fourth edge) of the chip 700c. The plurality of pad interconnects 520c may be a plurality of partial pad interconnects, since portions of the pad interconnects may have been removed and/or destroyed during singulation. Some of the memory cell structures from the plurality of memory cell structures 630c may be a plurality of partial memory cell structures, since portions of the memory cell structures may have been removed and/or destroyed during singulation. The plurality of memory cell structures may be destroyed without affecting the performance of the chip 700c, since the plurality of memory cell structures 630c is not designed to be operational and/or functioning during the operation of the chip 700c. Moreover, the plurality of memory cell structures 630c may not be electrically coupled to the memory portion 530c. The plurality of memory cell structures 630c may include memory cell structures with different memory capacity and/or memory density.

The chip 700d includes a memory portion 530d, a plurality of pad interconnects 540d, a plurality of pad interconnects 520d, a plurality of memory cell structures 630d. The plurality of pad interconnects 520d and the plurality of memory cell structures 630d may be located along one or more edges (e.g., first edge, second edge, third edge, fourth edge) of the chip 700d. The plurality of pad interconnects 520d may be a plurality of partial pad interconnects, since portions of the pad interconnects may have been removed and/or destroyed during singulation. Some of the memory cell structures from the plurality of memory cell structures 630d may be a plurality of partial memory cell structures, since portions of some of the memory cell structures may have been removed and/or destroyed during singulation. For example, the plurality of memory cell structures 630cd are at least partially destroyed. The plurality of memory cell structures may be destroyed without affecting the performance of the chip 700d, since the plurality of memory cell structures 630d is not designed to be operational and/or functioning during the operation of the chip 700d. Moreover, the plurality of memory cell structures 630d may not be electrically coupled to the memory portion 530d. The plurality of memory cell structures 630d and/or the plurality of memory cell structures 630cd may include memory cell structures with different memory capacity and/or memory density.

FIG. 8 illustrates a conceptual block diagram of a memory cell structure 800. The memory cell structure 800 may represent any of memory cell structures described in the disclosure. The memory cell structure 800 may be used for wafer quality assessment prior to formation of a high-bandwidth three-dimensional (3D) stacked memory chip of FIG. 2, according to various aspects of the present disclosure.

FIG. 8 illustrates a memory cell structure 800 configured for a DRAM cell array test, according to various aspects of the present disclosure. As shown in FIG. 8, the memory cell structure 800 may be configured for a simplified DRAM cell function test. For example, the simplified DRAM cell function test reduces the number of DRAM pads by providing pins, including a DRAM cell array structure with a single data pin (DQ) that performs DRAM cell functions through power supplied by VDD1/VDD2/VDDQ supply pins, a clock pin (CK), an address pin, and a control pin. Reducing the DRAM test pads is possible because the DRAM cell test functions are used to evaluate DRAM wafer quality. Consequently, the single DQ pin is configured to supply compressed DQ numbers according to a Boolean method.

In some implementations, DRAM voltage generators are connected to the VDD1/VDD2/VDDQ supply pins of the memory cell structure 800. Subsequently, the DRAM voltage generators are disconnected, to prevent these connections from impacting the actual DRAM die after 3D DRAM stacking. For example, these DRAM voltage generators are connected using a fuse option or using a generator connection selector circuit (not shown). Additionally, the memory cell structure 800 can be configured to operate according to a daisy chain, which simplifies the cell array connection monitoring to project a more accurate DRAM wafer yield.

These micro-structure test results can be simplified by implementing a Boolean function circuit (e.g., data compression mode), to save the test time, such as using the single DQ pin of the memory cell structure 800. In some implementations, micro-cell array placements are provided on any location having desired process effects for improved DRAM wafer yield projection. Additionally, the memory cell structures may include TSV connections. As recognized by those of skill in the art, any number of memory cell structures can be added on the wafer scribe line.

In some implementations, the micro-structures are added at defective photo lithography margin areas or defective process margin areas. The placement of multiple memory cell array micro-structures on the wafer scribe line is specified to follow the process uniformity coverage on the wafer. The disclosed memory cell structures reduce reliance on the DRAM test pads for performing DRAM wafer quality evaluation, which is beneficial due to DRAM wafer test time/cost. According to various aspects of the present disclosure, memory cell structure may be located vertically or horizontally on a plane of the DRAM wafer before the 3D DRAM wafer bonding process, for example, as shown in FIGS. 14A-14B.

### Exemplary Semiconductor Chip

FIG. 9 illustrates a cross sectional profile view of a chip 900. The chip 900 may represent the chip (e.g., 230-1, 230-2, 230-3, 230-4, 307a, 307b, 307b, 307c, 307d) and/or any other chip in the disclosure. The chip 900 may be a semiconductor chip. The chip 900 may be an integrated circuit (IC) chip. In some implementations, the chip 900 may be configured as a memory chip. In some implementations, the chip 900 may be configured as a logic chip.

The chip 900 includes a die substrate portion 902, a die interconnection portion 904, a plurality of pad interconnects 903, and/or a passivation layer 906. The chip 900 may further include a plurality of under bump metallization interconnects 970, a plurality of pillar interconnects 907 and/or a plurality of solder interconnects 909.

The die substrate portion 902 includes a die substrate 920 and an active region 922. The die substrate 920 may include silicon (Si). The active region 922 may be formed in the die substrate 920 and/or a surface of the die substrate 920. The active region 922 may include a plurality of logic cells and/or a plurality of transistors. One or more transistors may define a logic cell. The plurality of logic cells may include functioning logic cells when the integrated device is in operation. The plurality of transistors may include functioning transistors. Different implementations may use different types of transistors, such as a field effect transistor (FET), planar FET, finFET, and a gate all around FET. In some implementations, a front end of line (FEOL) process may be used to fabricate the plurality of cells and/or transistors in and/or over the die substrate 920. In some implementations, the die substrate portion 902 may include a plurality of through substrate vias 923 that extend through the die substrate 920. A metallization portion 905 may be coupled to the die substrate 920. The metallization portion 905 may be a back side metallization portion. The metallization portion 905 may include a plurality of metallization interconnects (e.g., back side metallization interconnects) that are coupled to the through substrate vias 923 that extend through the die substrate 920. Although not shown a passivation layer (e.g., similar to the passivation layer 906) may be formed on the back side of the chip 900. The passivation layer may be formed on the back side of the die substrate 920.

The die interconnection portion 904 is coupled to the die substrate portion 902. For example, the die interconnection portion 904 is coupled to the die substrate 920. The die interconnection portion 904 includes at least one dielectric layer 940, a plurality of capacitors 941 and a plurality of die interconnects 942. In some implementations, the at least one dielectric layer 940 may include silicon dioxide (SiO₂) or silicon nitride (SiN). The die interconnection portion 904 may be configured to be electrically coupled to the active region 922. For example, the plurality of capacitors 941 and/or the plurality of die interconnects 942 may be configured to be electrically coupled to the active region 922. Thus, the plurality of capacitors 941 and/or the plurality of die interconnects 942 may be configured to be electrically coupled to the plurality of logic cells and/or plurality of transistors. The plurality of capacitors 941 may include a plurality of deep trench capacitors. In some implementations, a back end of line (BEOL) process may be used to fabricate the die interconnection portion 904. The die interconnection portion 904 may be a BEOL die interconnection portion. The plurality of die interconnects 942 may include copper (Cu). In some implementations, the plurality of capacitors 941 and/or the plurality of active region 922 may be configured a memory portion and/or a memory block. The die interconnection portion 904 may be formed over the die substrate portion 902.

The plurality of pad interconnects 903 are coupled to the die interconnection portion 904. The plurality of pad interconnects 903 may be coupled to the plurality of die interconnects 942.

The passivation layer 906 is coupled to the die interconnection portion 904. The passivation layer 906 may be formed and coupled to a surface of the dic interconnection portion 904. The passivation layer 906 may be coupled to and touch the at least one dielectric layer 940. The passivation layer 906 may be formed and coupled to part of the plurality of pad interconnects 903. In some implementations, the passivation layer 906 may include silicon nitride (SiN). However, different implementations may use different materials for the passivation layer 906. The passivation layer 906 may include a different material from the at least one dielectric layer 940. The plurality of under bump metallization interconnects 970 may be coupled to the plurality of pad interconnects 903. The plurality of pillar interconnects 907 may be coupled to the plurality of pad interconnects 903 through the plurality of under bump metallization interconnects 970. The plurality of solder interconnects 909 may be coupled to the plurality of pillar interconnects 907. The plurality of under bump metallization interconnects 970, the plurality of pillar interconnects 907 and/or the plurality of solder interconnects 909 may be considered part of the chip 101. In some implementations, the plurality of pillar interconnects 907 and/or the plurality of under bump metallization interconnects 970 may be optional. In such instances, the plurality of solder interconnects 909 may be coupled to the plurality of pad interconnects 903.

The chip 900 includes a region 908. The region 908 may be a region that may correspond to a scribe line region of a wafer. The scribe line region of a wafer is an area of the wafer where a saw may be used to singulate the wafer into individual chips. The region 908 may be located along the edges (e.g., first edge, second edge, third edge, fourth) of the chip 900. In some implementations, the region 908 may include a keep out zone of the chip 900. In some implementations, a keep out zone of the chip 900 may be a region of the chip where any component that is supposed to function during the operation of the chip 900 should not be located in that region, since that region may get damaged and/or destroyed during the fabrication process.

The region 908 includes at least one memory cell structure 901 and at least one pad interconnect 930. The at least one memory cell structure 901 may include an active region 924, a plurality of capacitors 943 and a plurality of die interconnects 944. The plurality of capacitors 943 may include a plurality of deep trench capacitors. The at least one memory cell structure 901 may correspond to the plurality of memory cell structures as described in at least FIG. 7. The at least one pad interconnect 930 may correspond to a pad interconnect from the plurality of pad interconnects 520. During the singulation of the wafer to form the chip 900, some portions and/or components of the at least one memory cell structure 901 may be destroyed and/or removed. Similarly, during the singulation of the wafer to form the chip 900, some portions and/or components of the at least one pad interconnect 930 may be destroyed and/or removed. It is noted that the at least one memory cell structure 901 may be free of any electrical coupling with the active region 922 of the chip 900. Thus, the at least one memory cell structure 901 may be free of any electrical coupling with one or more memory blocks of the chip 900. In some implementations, the at least one memory cell structure 901 may be defective, non-operational and/or non-functioning (e.g., never operational, never functioning) when the chip 900 is operational.

The plurality of capacitors 943 may include a capacitor, such as a deep trench capacitor. The capacitor includes a first electrode, a capacitor dielectric layer, and a second electrode. The capacitor dielectric layer may be located between the first electrode and the second electrode. The first electrode may be a bottom electrode and the second electrode may be a top electrode. In some implementations, the first electrode may include heavily doped polysilicon or tungsten (W). In some implementations, the capacitor dielectric layer may be a high K dielectric layer, such as zirconium dioxide (ZrO2) and oxide-nitride-oxide (ONO). In some implementations, the second electrode may include titanium nitride (TIN). However, it is noted that different materials may be used for the first electrode, the second electrode and/or the capacitor dielectric layer. In some implementations, there may be heavily doped polysilicon or tungsten (W) between the second electrode of adjacent capacitors. It is noted that capacitors from the plurality of capacitors 941 may be configured in a similar way as the plurality of capacitors 943. The first electrode may be coupled to and touch an interconnect. The first electrode may be coupled to and touch another interconnect.

FIGS. 10-12 illustrate various configurations of how a chip may be coupled to another chip. FIG. 10 illustrates a chip 1000 that is coupled to a chip 900 through hybrid bonding. The chip 1000 may be similar to the chip 900, and thus may include similar components that are arranged and/or configured in a similar manner as the chip 900. A back side of the chip 1000 is coupled to the back side of the chip 900 through hybrid bonding. Hybrid bonding may include metal to metal bonding (e.g., copper to copper bonding). As shown in FIG. 10, metallization interconnects of the metallization portion 905 of the chip 1000 are coupled to and touch metallization interconnects of the metallization portion 905 of the chip 900. The metallization portion 905 of a chip may be a back side metallization portion of the chip. There may be at least one passivation layer (that is similar to the passivation layer 906) between the back side of the chip 900 and the back side of the chip 1000. The chip 1000 includes at least one memory cell structure 1001. The at least one memory cell structure 1001 may be similar to the at least one memory cell structure 901.

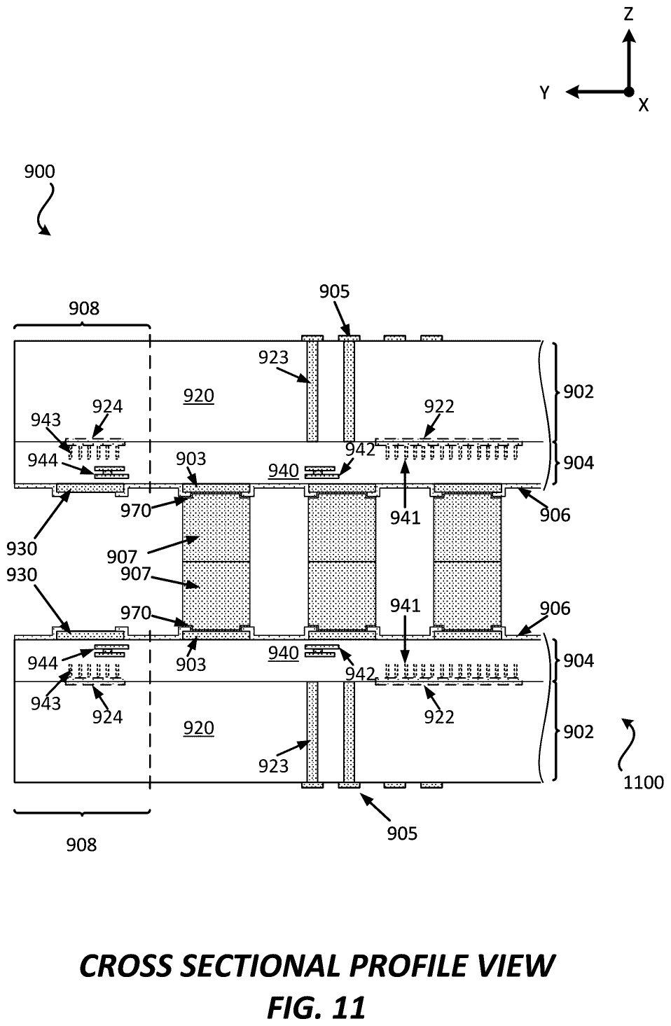

FIG. 11 illustrates a chip 1100 that is coupled to a chip 900 through hybrid bonding. The chip 1100 may be similar to the chip 900, and thus may include similar components that are arranged and/or configured in a similar manner as the chip 900. A front side of the chip 1100 is coupled to the front side of the chip 900 through hybrid bonding. As shown in FIG. 11, pillar interconnects of the plurality of pillar interconnects 907 of the chip 1100 are coupled to and pillar interconnects of the plurality of pillar interconnects 907 of the chip 900. In some implementations, the pillar interconnects may be optional. In such instances, the plurality of pad interconnects 903 of the chip 1100 may be coupled to and touch the plurality of pad interconnects 903 of the chip 900. In another example, the plurality of pad interconnects 903 of the chip 1100 may be coupled to and touch the plurality of pillar interconnects 907 of the chip 900. In another example, the plurality of pad interconnects 903 of the chip 900 may be coupled to and touch the plurality of pillar interconnects 907 of the chip 1100.

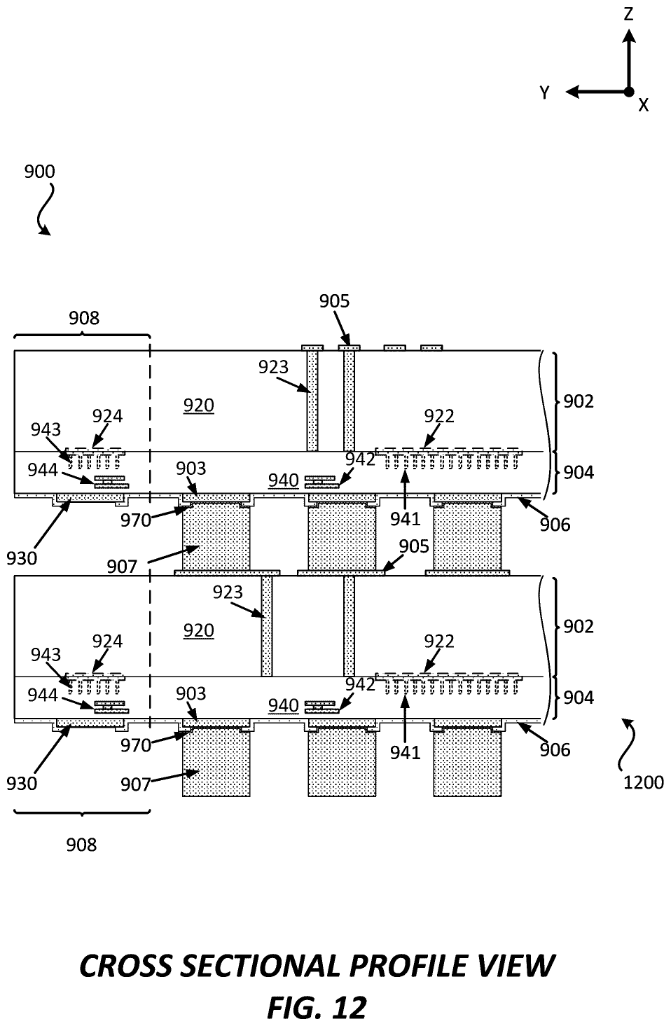

FIG. 12 illustrates a chip 1200 that is coupled to a chip 900 through hybrid bonding. The chip 1200 may be similar to the chip 900, and thus may include similar components that are arranged and/or configured in a similar manner as the chip 900. A back side of the chip 1200 is coupled to the front side of the chip 900 through hybrid bonding. As shown in FIG. 12, pillar interconnects of the plurality of pillar interconnects 907 of the chip 900 are coupled to and touch metallization interconnects of the metallization portion 905 of the chip 1200. The metallization portion 905 of a chip may be a back side metallization portion of the chip. In some implementations, the plurality of pillar interconnects 907 may be optional. In such instances, the plurality of pad interconnects 903 of the chip 900 may be coupled to and touch metallization interconnects of the metallization portion 905 of the chip 1200.

A chip can be a semiconductor chip. A chip can be an integrated circuit (IC) chip. A chip can include a plurality of transistors configured to perform logic operations and/or other functionalities. A chip can include capacitors and/or resistors. A chip can include a semiconductor substrate (e.g., silicon substrate) and interconnects. A chip can include a die (e.g., semiconductor bare die). The die can include a plurality of transistors configured to perform logic operations and/or other functionalities.

A chip may be a type of integrated circuit (IC) device and/or a type of an integrated device. A chip may include a power management integrated circuit (PMIC). A chip may include an application processor. A chip may include a modem. A chip may include a radio frequency (RF) device, a passive device, a filter, a capacitor, an inductor, an antenna, a transmitter, a receiver, a gallium arsenide (GaAs) based chip, a surface acoustic wave (SAW) filter, a bulk acoustic wave (BAW) filter, a light emitting diode (LED) integrated device, a silicon (Si) based chip, a silicon carbide (SiC) based chip, a memory, power management processor, and/or combinations thereof. A chip may include at least one electronic circuit (e.g., first electronic circuit, second electronic circuit, etc . . . ). A chip may include an input/output (I/O) hub. A chip may be an example of an electrical component and/or electrical device.

In some implementations, a chip can be a chiplet. A chiplet may be fabricated using a process that provides better yields compared to other processes used to fabricate other types of chips and/or dies, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one or more integrated devices). As mentioned above, using several chiplets that perform several functions may reduce the overall cost of a package relative to using a single chip to perform all of the functions of a package. In some implementations, one of more of chiplets (e.g., 105) described in the disclosure may be fabricated using the same technology node or two or more different technology nodes. For example, a chip may be fabricated using a first technology node, and a chiplet may be fabricated using a second technology node that is not as advanced as the first technology node. In such an example, the chip may include components (e.g., interconnects, transistors) that have a first minimum size, and the chiplet may include components (e.g., interconnects, transistors) that have a second minimum size, where the second minimum size is greater than the first minimum size. In some implementations, a first chip and a second chip of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate a chiplet and/or a die. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the chip is locked into one technology node. To optimize the cost of a package, some of the functions can be implemented in different chiplets, where different integrated devices and/or chiplets may be fabricated using different technology nodes to reduce overall costs. For example, functions that require the use of the most advanced technology node may be implemented in a chip, and functions that can be implemented using a less advanced technology node can be implemented in another chip and/or one or more chiplets. One example, would be a chip, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single chip to perform all the functions of the package.

Another advantage of splitting the functions into several chips, dies and/or chiplets, is that it allows improvements in the performance of the package without having to redesign every single chip and/or chiplet. For example, if a configuration of a package uses a first chip and a first chiplet, it may be possible to improve the performance of the package by changing the design of the first chip, while keeping the design of the first chiplet the same. Thus, the first chiplet could be reused with the improved and/or different configured first chip. This saves cost by not having to redesign the first chiplet, when packages with improved chips are fabricated.

The package may be implemented in a radio frequency (RF) package. The RF package may be a radio frequency front end (RFFE) package. A package may be configured to provide Wireless Fidelity (WiFi) communication and/or cellular communication (e.g., 2G, 3G, 4G, 5G, 6G). The packages may be configured to support Global System for Mobile (GSM) Communications, Universal Mobile Telecommunications System (UMTS), and/or Long-Term Evolution (LTE). The packages may be configured to transmit and receive signals having different frequencies and/or communication protocols.

### Exemplary Flow Chart of a Method for Testing and Assessing a Wafer

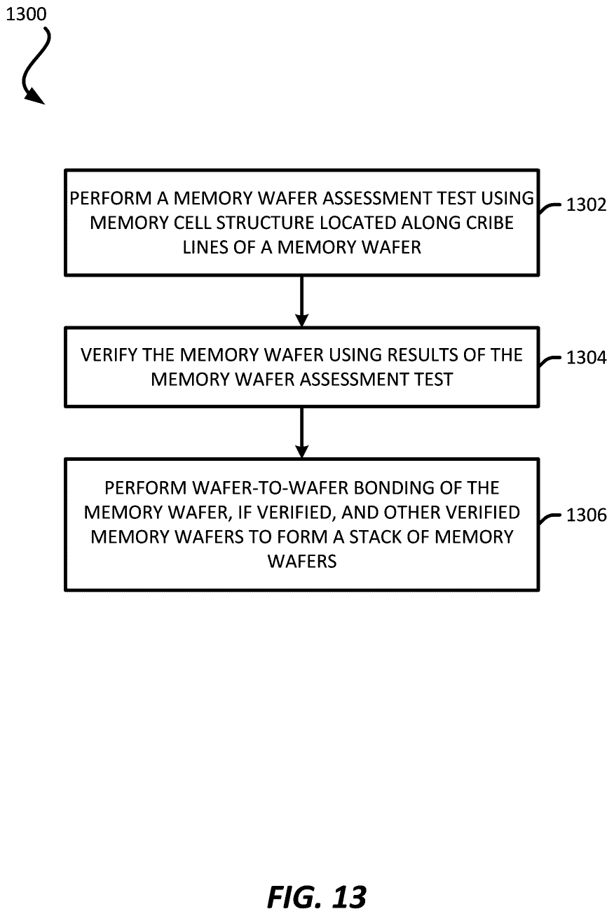

In some implementations, testing, assessing a wafer and bonding wafers includes several processes. FIG. 13 illustrates an exemplary flow diagram of a method 1300 for testing and bonding wafers together. In some implementations, the method 1300 of FIG. 13 may be used to test and bond several wafers, as described in the disclosure. However, the method 1300 may be used to test and bond any wafers described in the disclosure.

It should be noted that the method 1300 of FIG. 13 may combine one or more processes in order to simplify and/or clarify the method for testing and bonding wafers. In some implementations, the order of the processes may be changed or modified.

The method performs (at 1302) a wafer assessment test using the plurality of memory cell structures. For example, test probes may be coupled to test pads of the memory cell structures to test the plurality of memory cell structures. The plurality of memory cell structures may be located along scribe lines of the wafer and/or in a scribe line region of the wafer. For example, the method may check whether the various capacity or density of the memory cell structures work as intended.

The method verifies (at 1304) the wafer using results of the assessment test of the wafer. For example, the method may determine and/or verify the effective yield and/or probable yield of the wafer based on the results of the assessment test. If the yield is too low and/or below a threshold amount, then that particular wafer may be discarded. However, if the yield is expected to be high and/or above a threshold amount, then that particular wafer may be used in a wafer to wafer bonding process.

The method performs (at 1306) a wafer to wafer bonding process, using wafers that have passed the assessment test. A wafer to wafer bonding process may include a wafer to wafer hybrid bonding process. Several wafers (e.g., two or more wafers) may be bonded together to form a stack of wafers. Once wafers have been coupled and/or bonded to each other, singulation may occur along the scribe lines, which results in a stack of chips (e.g., stack of memory chips).

In some implementations, as mentioned above, memory cell structures are provided on horizontal/vertical DRAM wafer scribe lines to enable DRAM cell functional testing. The memory cell structures are located on the scribe lines and/or scribe line regions, and can reduce the wafer-to-wafer hybrid bonding issue on the actual DRAM chip area by moving a test pad area on the actual DRAM chip area to the scribe line region. Inserting the memory cell structures on the scribe line and/or scribe line region provides improved wafer assessment testing.

### Exemplary Sequence for Fabricating a Stack of Chips

In some implementations, fabricating a stack of chips includes several processes. FIGS. 14A-14B illustrate an exemplary sequence for providing or fabricating a stack of chips. In some implementations, the sequence of FIGS. 14A-14B may be used to provide or fabricate the stack of chips 303. However, the process of FIGS. 14A-14B may be used to fabricate any of the stack of chips described in the disclosure.

It should be noted that the sequence of FIGS. 14A-14B may combine one or more stages in order to simplify and/or clarify the sequence for providing or fabricating a stack of chips. In some implementations, the order of the processes may be changed or modified. In some implementations, one or more of processes may be replaced or substituted without departing from the scope of the disclosure.

Stage 1, as shown in FIG. 14A, illustrates a state after a wafer 600a is provided. The wafer 600a may a memory wafer. The wafer 600a may include uncut dies and/or uncut chips. The wafer 600a may be the wafer 600. The wafer 600a may include a plurality of memory cell structures, as described in the disclosure. The plurality of memory cell structures may be located in the scribe regions of the wafer 600a.

Stage 2 illustrates a state after a testing of the wafer 600a. The wafer 600a may be tested through the plurality of memory cell structures of the wafer 600a. Testing probes may be coupled to testing pads of the wafer 600a. If the wafer 600a meets certain criteria and/or threshold values, the wafer 600a may be used in a wafer to wafer bonding process. However, if the wafer 600a does not meet certain criteria and/or does not meet certain threshold values, the wafer 600a may be discarded. Examples of criteria and/or threshold values are described above in at least FIG. 13. In some implementations, several wafers are provided and tested.

Stage 3 illustrates a state after a wafer 600a is bonded to a wafer 600b. The wafer 600b is also bonded to the wafer 600c. The wafer 600b and the wafter 600c may be similar to the wafer 600a. The wafer 600b and the wafer 600c can each include a plurality of memory cell structures. The wafer 600b and the wafer 600c may have been tested in a similar manner as the wafer 600a. One or more hybrid bonding processes may be used to bond the wafer 600a, the wafer 600b and the wafer 600c together. In some implementations, more than 3 wafers may be bonded together. In some implementations, the wafers may be coupled together in a front side to back side manner. In some implementations, the wafers may be coupled together in a front side to front side manner. In some implementations, the wafers may be coupled together in a back side to back side manner.

Stage 4 illustrates a state after the wafer 600a, the wafer 600b and the wafer 600c are collectively tested together. Testing probes may be coupled to pad interconnects of the wafer 600a and/or the wafer 600c to test the stack of wafers comprising the wafer 600a, the wafer 600b and the wafer 600c.

Stage 5, as shown in FIG. 14B, illustrates a state after a wafer 1400 is coupled and bonded to the wafer 600c. A hybrid bonding process may be used to couple the wafer 1400 to the wafer 600c. The wafer 1400 may include a logic wafer. The wafer 1400 may include a plurality of uncut dies and/or a plurality of uncut chips. The uncut chips may be uncut System on Chips (SoCs). The uncut chips may be uncut logic chips.

Stage 6 illustrates a state after a plurality of solder interconnects 1410 are coupled to the wafer 1400. A solder reflow process may be used to couple the plurality of solder interconnects 1410 to the wafer 1400. Stage 6 may illustrate a stack of wafers 1420 that includes a wafer 600a, a wafer 600b, a wafer 600c, a wafer 1400 and a plurality of solder interconnects 1410.

Stage 7 illustrates a state after singulation of the stack of wafers 1420 into a plurality of a stack of chips 1430. The stack of chips 1430 may include a first memory chip, a second memory chip, a third memory chip and a logic chip. The first memory chip, the second memory chip and/or the third memory chip may each include at least one memory cell structure. The memory cell structure of a memory chip may vertically overlap with a memory cell structure of another memory chip.

### Exemplary Flow Diagram of a Method for Fabricating a Stack of Chips

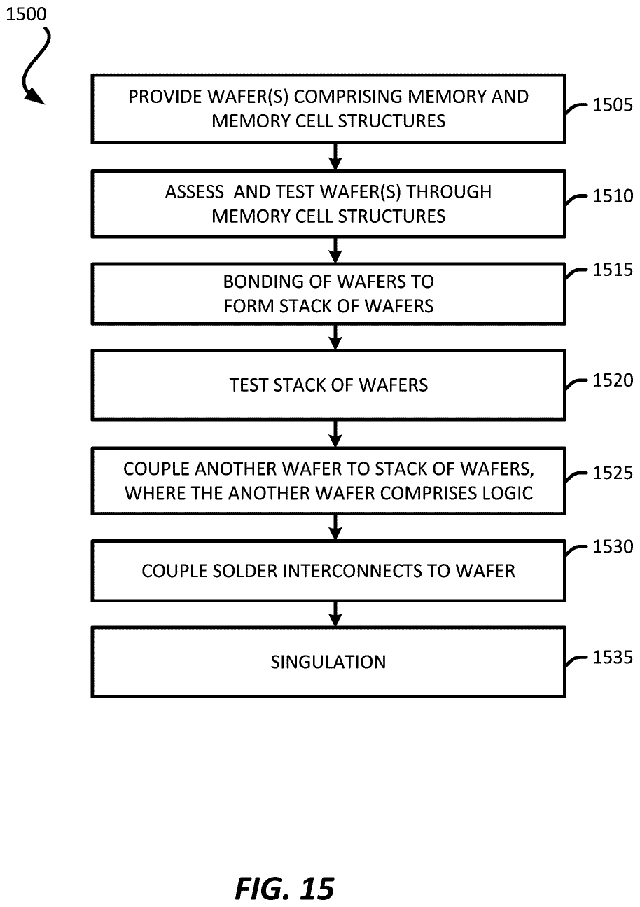

In some implementations, fabricating a stack of chips includes several processes. FIG. 15 illustrates an exemplary flow diagram of a method 1500 for providing or fabricating a stack of chips. In some implementations, the method 1500 of FIG. 15 may be used to provide or fabricate the stack of chips 303 described in the disclosure. However, the method 1500 may be used to provide or fabricate any of the stack of chips described in the disclosure.

It should be noted that the method 1500 of FIG. 15 may combine one or more processes in order to simplify and/or clarify the method for providing or fabricating a stack of chips. In some implementations, the order of the processes may be changed or modified.

The method provides (at 1505) a wafer comprising a memory portion and memory cell structures. Stage 1 of FIG. 14A, illustrates and describes an example of a state after a wafer 600a is provided. The wafer 600a may a memory wafer. The wafer 600a may include uncut dies and/or uncut chips. The wafer 600a may be the wafer 600. The wafer 600a may include a plurality of memory cell structures, as described in the disclosure. The plurality of memory cell structures may be located in the scribe regions of the wafer 600a.

The method assesses and tests (at 1510) the wafer through the memory cell structures. Stage 2 of FIG. 14A, illustrates and describes an example of a state after a testing of the wafer 600a. The wafer 600a may be tested through the plurality of memory cell structures of the wafer 600a. Testing probes may be coupled to testing pads of the wafer 600a. If the wafer 600a meets certain criteria and/or threshold values, the wafer 600a may be used in a wafer to wafer bonding process. However, if the wafer 600a does not meet certain criteria and/or does not meet certain threshold values, the wafer 600a may be discarded. Examples of criteria and/or threshold values are described above in at least FIG. 13. In some implementations, several wafers are provided and tested.

The method bonds (at 1515) two or more wafer together to form a stack of wafers. Stage 3 of FIG. 14A, illustrates and describes an example of a state after a wafer 600a is bonded to a wafer 600b. The wafer 600b is also bonded to the wafer 600c. The wafer 600b and the wafter 600c may be similar to the wafer 600a. The wafer 600b and the wafer 600c can each include a plurality of memory cell structures. The wafer 600b and the wafer 600c may have been tested in a similar manner as the wafer 600a. One or more hybrid bonding processes may be used to bond the wafer 600a, the wafer 600b and the wafer 600c together. In some implementations, more than 3 wafers may be bonded together. In some implementations, the wafers may be coupled together in a front side to back side manner. In some implementations, the wafers may be coupled together in a front side to front side manner. In some implementations, the wafers may be coupled together in a back side to back side manner.

The method tests (at 1520) the stack of wafers. Stage 4 of FIG. 14A, illustrates a state after the wafer 600a, the wafer 600b and the wafer 600c are collectively tested together. Testing probes may be coupled to pad interconnects of the wafer 600a and/or the wafer 600c to test the stack of wafers comprising the wafer 600a, the wafer 600b and the wafer 600c.

The method couples (at 1525) another wafer to the stack of wafers. Stage 5 of FIG. 14B, illustrates and describes an example of a state after a wafer 1400 is coupled and bonded to the wafer 600c. A hybrid bonding process may be used to couple the wafer 1400 to the wafer 600c. The wafer 1400 may include a logic wafer. The wafer 1400 may include a plurality of uncut dies and/or a plurality of uncut chips. The uncut chips may be uncut System on Chips (SoCs). The uncut chips may be uncut logic chips.

The method couples (at 1530) a plurality of solder interconnects to the wafer. Stage 6 of FIG. 14B, illustrates and describes an example of a state after a plurality of solder interconnects 1410 are coupled to the wafer 1400. A solder reflow process may be used to couple the plurality of solder interconnects 1410 to the wafer 1400. Stage 6 may illustrate a stack of wafers 1420 that includes a wafer 600a, a wafer 600b, a wafer 600c, a wafer 1400 and a plurality of solder interconnects 1410.

The method singulates (at 1535) the stack of wafers. Stage 7 of FIG. 14B, illustrates and describes an example of a state after singulation of the stack of wafers 1420 into a plurality of a stack of chips 1430. The stack of chips 1430 may include a first memory chip, a second memory chip, a third memory chip and a logic chip. The first memory chip, the second memory chip and/or the third memory chip may each include at least one memory cell structure. The memory cell structure of a memory chip may vertically overlap with a memory cell structure of another memory chip.

### Exemplary Sequence for Fabricating a Package Comprising a Stack of Chips

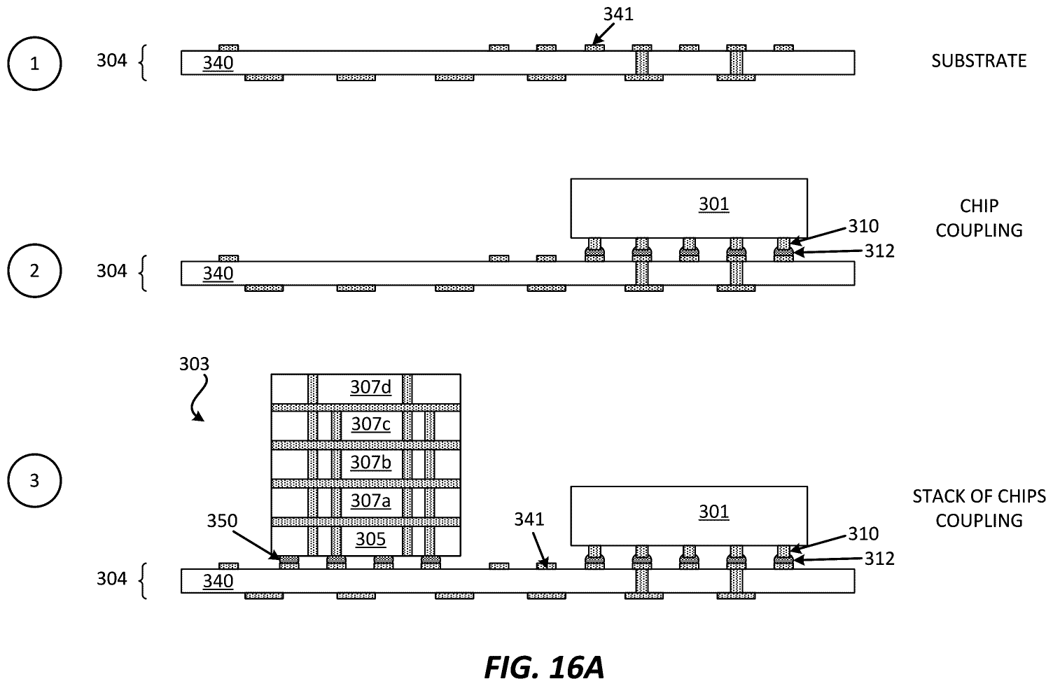

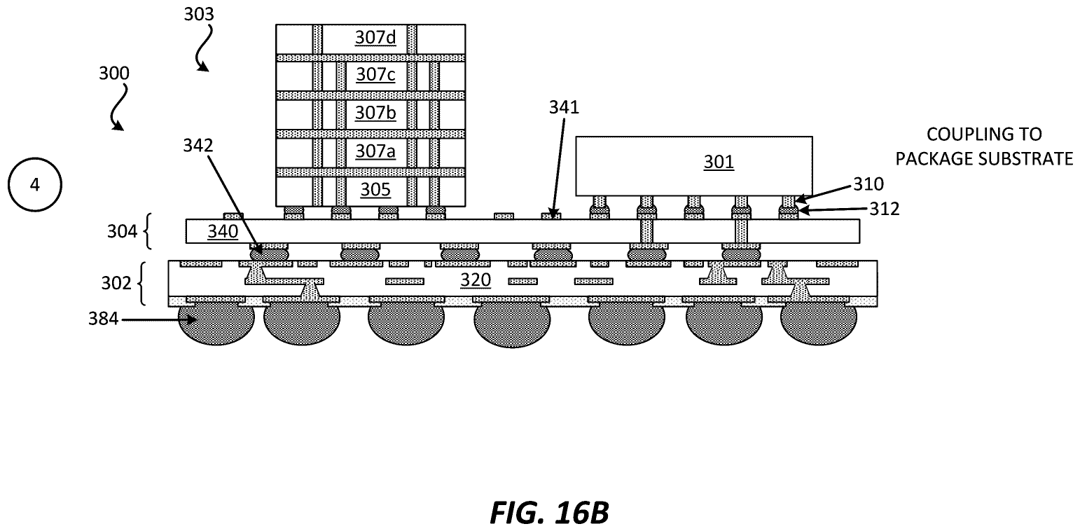

In some implementations, fabricating a package includes several processes. FIGS. 16A-16B illustrate an exemplary sequence for providing or fabricating a package. In some implementations, the sequence of FIGS. 16A-16B may be used to provide or fabricate the package 300. However, the process of FIGS. 16A-16B may be used to fabricate any of the packages described in the disclosure.

It should be noted that the sequence of FIGS. 16A-16B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 16A, illustrates a state after a substrate 304 is provided. The substrate 304 includes at least one dielectric layer 340 and a plurality of interconnects 341. The substrate 304 may be an interposer.

Stage 2 illustrates a state after the chip 301 is coupled to the substrate 304 through a plurality of pillar interconnects 310 and a plurality of solder interconnects 312. The plurality of solder interconnects 312 may be coupled to the plurality of interconnects 341 of the substrate 304 through a solder reflow process.

Stage 3 illustrates a state after the stack of chips 303 is coupled to the substrate 304 through a plurality of solder interconnects 350. The plurality of solder interconnects 350 may be coupled to the plurality of interconnects 341 of the substrate 304 through a solder reflow process. The stack of chips 303 is located laterally adjacent and/or near the chip 301. The stack of chips 303 may include a chip 305, a chip 307a, a chip 307b, a chip 307c and a chip 307d. In some implementations, the stack of chips 303 may be coupled to the substrate 304. The chip 307a, the chip 307b, the chip 307c and/or the chip 307d may include at least one memory cell structure located along at least one edge of the respective chip.

Stage 4, as shown in FIG. 16B, illustrates a state after the substrate 304 is coupled to the substrate 302 through a plurality of solder interconnects 342. The substrate 302 may include at least one dielectric layer 320 and a plurality of interconnects 321. The plurality of solder interconnects 342 may be coupled to the plurality of interconnects 321 of the substrate 302 through a solder reflow process.

### Exemplary Flow Diagram of a Method for Fabricating a Package Comprising a Stack of Chips

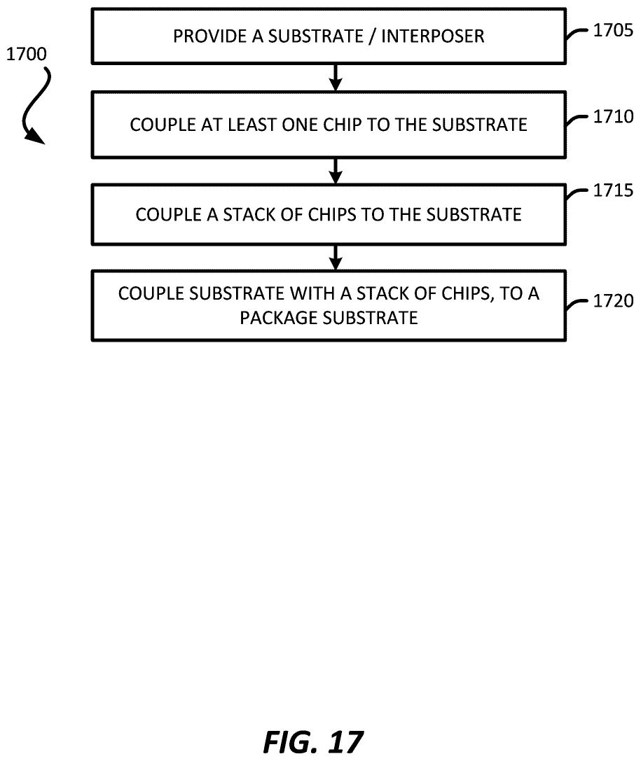

In some implementations, fabricating a package includes several processes. FIG. 17 illustrates an exemplary flow diagram of a method 1700 for providing or fabricating a package. In some implementations, the method 1700 of FIG. 17 may be used to provide or fabricate the package 300 described in the disclosure. However, the method 1700 may be used to provide or fabricate any of the packages described in the disclosure.

It should be noted that the method 1700 of FIG. 17 may combine one or more processes in order to simplify and/or clarify the method for providing or fabricating a package. In some implementations, the order of the processes may be changed or modified.

The method provides (at 1705) a substrate. Stage 1 of FIG. 16A, illustrates a state after a substrate 304 is provided. The substrate 304 includes at least one dielectric layer 340 and a plurality of interconnects 341. The substrate 304 may be an interposer.

The method couples (at 1710) a chip to the substrate. Stage 2 of FIG. 16A, illustrates a state after the chip 301 is coupled to the substrate 304 through a plurality of pillar interconnects 310 and a plurality of solder interconnects 312. The plurality of solder interconnects 312 may be coupled to the plurality of interconnects 341 of the substrate 304 through a solder reflow process.

The method couples (at 1715) a stack of chips to the substrate. Stage 3 of FIG. 16A, illustrates a state after the stack of chips 303 is coupled to the substrate 304 through a plurality of solder interconnects 350. The plurality of solder interconnects 350 may be coupled to the plurality of interconnects 341 of the substrate 304 through a solder reflow process. The stack of chips 303 is located laterally adjacent and/or near the chip 301. The stack of chips 303 may include a chip 305, a chip 307a, a chip 307b, a chip 307c and a chip 307d. In some implementations, the stack of chips 303 may be coupled to the substrate 304. The chip 307a, the chip 307b, the chip 307c and/or the chip 307d may include at least one memory cell structure located along at least one edge of the respective chip.

The method couples (at 1720) the substrate with a stack of chips, to a package substrate. Stage 4 of FIG. 16B, illustrates a state after the substrate 304 is coupled to the substrate 302 through a plurality of solder interconnects 342. The substrate 302 may include at least one dielectric layer 320 and a plurality of interconnects 321. The plurality of solder interconnects 342 may be coupled to the plurality of interconnects 321 of the substrate 302 through a solder reflow process.

### Exemplary Electronic Devices

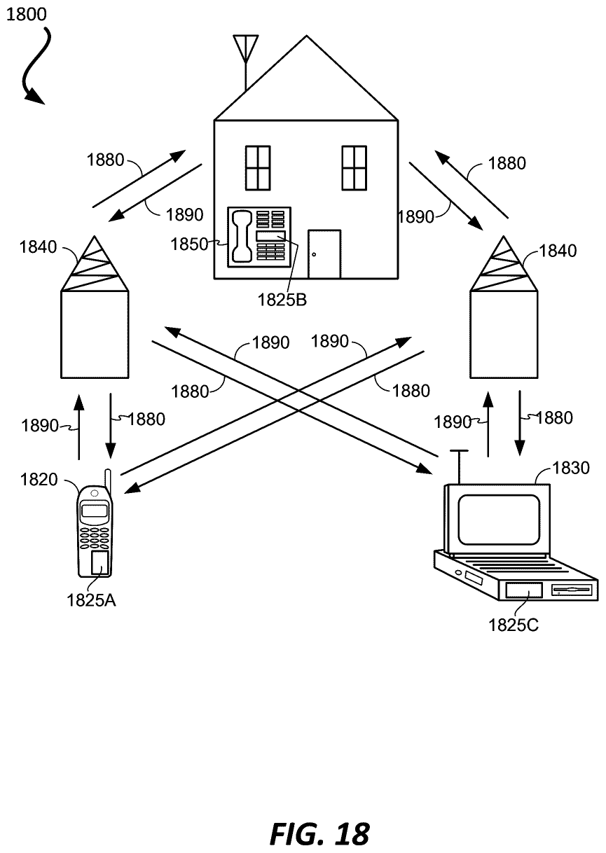

FIG. 18 is a block diagram showing an exemplary wireless communications system 1800 in which a configuration of the disclosure may be advantageously employed. For purposes of illustration, FIG. 18 shows three remote units 1820, 1830, and 1850, and two base stations 1840. It will be recognized that wireless communications systems may have many more remote units and base stations. Remote units 1820, 1830, and 1850 include integrated circuit (IC) devices 1825A, 1825C, and 1825B that include the disclosed memory cell array micro-structures in three-dimensional (3D) stacked DRAM for improved yield. It will be recognized that other devices may also include the disclosed the memory cell array micro-structures in 3D stacked DRAM for improved yield, such as the base stations, switching devices, and network equipment. FIG. 18 shows forward link signals 1880 from the base stations 1840 to the remote units 1820, 1830, and 1850, and reverse link signals 1890 from the remote units 1820, 1830, and 1850 to the base stations 1840.

In FIG. 18, remote unit 1820 is shown as a mobile telephone, remote unit 1830 is shown as a portable computer, and remote unit 1850 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 18 illustrates remote units according to aspects of the present disclosure, the disclosure is not limited to these exemplary illustrated units. Aspects of the present disclosure may be suitably employed in many devices, which include the disclosed the memory cell array micro-structures in 3D stacked DRAM for improved yield.

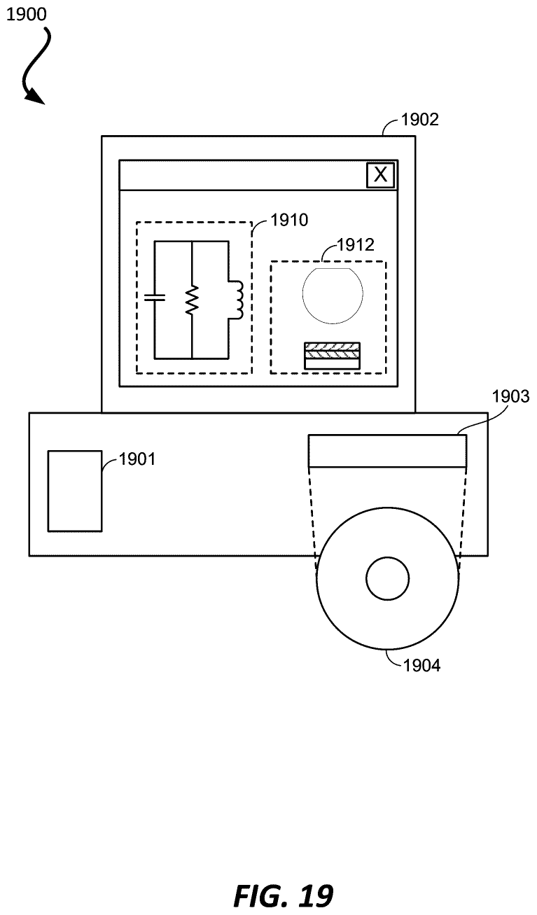

FIG. 19 is a block diagram illustrating a design workstation used for circuit, layout, and logic design of a semiconductor component, such as the vertical bank redundancy in three-dimensional (3D) stacked dynamic random-access memory (DRAM) for improved yield disclosed above. A design workstation 1900 includes a hard disk 1901 containing operating system software, support files, and design software such as Cadence or OrCAD. The design workstation 1900 also includes a display 1902 to facilitate design of a circuit 1910 or an integrated circuit (IC) component 1912, such as the memory cell array micro-structures in 3D stacked DRAM for improved yield. A storage medium 1904 is provided for tangibly storing the design of the circuit 1910 or the IC component 1912 (e.g., the memory cell array micro-structures). The design of the circuit 1910 or the IC component 1912 may be stored on the storage medium 1904 in a file format such as GDSII or GERBER. The storage medium 1904 may be a CD-ROM, DVD, hard disk, flash memory, or other appropriate device. Furthermore, the design workstation 1900 includes a drive apparatus 1903 for accepting input from or writing output to the storage medium 1904.

Data recorded on the storage medium 1904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1904 facilitates the design of the circuit 1910 or the IC component 1912 by decreasing the number of processes for designing semiconductor wafers.

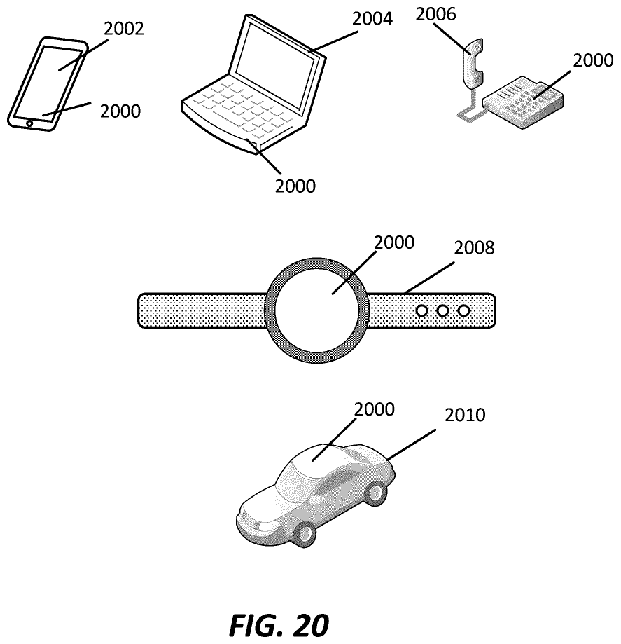

FIG. 20 illustrates various electronic devices that may be integrated with any of the aforementioned device, integrated device, integrated circuit (IC) package, integrated circuit (IC) device, semiconductor device, integrated circuit, die, chip, interposer, package, package-on-package (POP), System in Package (SiP), or System on Chip (SoC). For example, a mobile phone device 2002, a laptop computer device 2004, a fixed location terminal device 2006, a wearable device 2008, or automotive vehicle 2010 may include a device 2000 as described herein. The device 2000 may be, for example, any of the devices and/or integrated circuit (IC) packages described herein. The devices 2002, 2004, 2006 and 2008 and the vehicle 2010 illustrated in FIG. 20 are merely exemplary. Other electronic devices may also feature the device 2000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IOT) devices, servers, data centers, artificial intelligence (AI) centers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-13, 14A-14B, 15, 16A-16B, and 17-20 may be rearranged and/or combined into a single component, process, feature or function or embodied in several components, processes, or functions. Additional elements, components, processes, and/or functions may also be added without departing from the disclosure. It should also be noted FIGS. 1-13, 14A-14B, 15, 16A-16B, and 17-20 and its corresponding description in the present disclosure is not limited to dies and/or ICs. In some implementations, FIGS. 1-13, 14A-14B, 15, 16A-16B, and 17-20 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. An object that is coupled to another object may mean that the object is touching the other object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect, as used in the disclosure, can include various metal materials, such as copper and/or aluminum. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A device comprising: a substrate; and a stack of chips coupled to the substrate, wherein the stack of chips comprises: a logic chip; and a first memory chip coupled to the logic chip, wherein the first memory chip comprises: a first die substrate; a first plurality of memory cells; and a first plurality of memory cell structures located along at least one edge of the first memory chip.

Aspect 2: The device of aspect 1, wherein the first plurality of memory cell structures comprises: a first memory cell structure comprising a first memory capacity; and a second memory cell structure comprising a second memory capacity that is different from the first memory capacity.

Aspect 3: The device of aspect 2, wherein the first memory cell structure and the second memory cell structure are located along a first edge of the first memory chip.

Aspect 4: The device of aspect 2, wherein the first memory cell structure is located along a first edge of the first memory chip, and wherein the second memory cell structure is located along a second edge of the first memory chip.

Aspect 5: The device of aspect 2, wherein the first memory cell structure is a partial memory cell structure.

Aspect 6: The device of aspects 1 through 5, wherein the first plurality of memory cell structures is free of any electrical coupling with the first plurality of memory cells.

Aspect 7: The device of aspects 1 through 6, wherein the first plurality of memory cell structures comprises: a plurality of logical cells configured as memory; and a plurality of capacitors coupled to the plurality of logical cells.

Aspect 8: The device of aspects 1 through 7, wherein the first memory chip is a dynamic random access memory (DRAM) chip, wherein the first plurality of memory cells include operational logic cells when the chip is in operation, and wherein the first plurality of memory cell structures are non-operational when the chip is in operation.

Aspect 9: The device of aspects 1 through 8, wherein the stack of chips further comprises a second memory chip coupled to the first memory chip, and wherein the second memory chip comprises: a second die substrate; a second plurality of memory cells; and a second plurality of memory cell structures located along at least one edge of the second memory chip.

Aspect 10: The device of aspects 1 through 9, further comprising a first chip coupled to the substrate, wherein the first chip is located adjacent to the stack of chips.

Aspect 11: The device of aspect 10, wherein the logic chip is a first chiplet based on a first technology node, and wherein the first chip is a second chiplet based on a second technology node, that is different from the first technology node.

Aspect 12: The device of aspects 1 through 11, wherein the logic chip is a first chiplet based on a first technology node, and wherein the first memory chip is a second chiplet based on a second technology node, that is different from the first technology node.

Aspect 13: The device of aspect 12, wherein the first technology node specifies a first minimum dimension for transistor sizes for the first chiplet, wherein the second technology node specifies a second minimum dimension for transistor sizes for the second chiplet, and wherein the second minimum dimension is different than the first minimum dimension.

Aspect 14: The device of aspect 10, wherein the stack of chips is a high bandwidth memory (HBM), and wherein the first chip is implemented as a System on Chip (SoC).

Aspect 15: A chip comprising: a die substrate; a plurality of memory cells; and a plurality of memory cell structures located along at least one edge of the chip.

Aspect 16: The chip of aspect 15, wherein the plurality of memory cell structures comprises: a first memory cell structure comprising a first memory capacity; and a second memory cell structure comprising a second memory capacity that is different from the first memory capacity.

Aspect 17: The chip of aspect 16, wherein the first memory cell structure and the second memory cell structure are located along a first edge of the chip.

Aspect 18: The chip of aspect 16, wherein the first memory cell structure is a partial memory cell structure.

Aspect 19: The chip of aspects 15 through 18, wherein the plurality of memory cell structures is free of any electrical coupling with the plurality of memory cells.

Aspect 20: The chip of aspects 15 through 19, wherein the chip is a dynamic random access memory (DRAM) chip, wherein the plurality of memory cells include operational logic cells when the chip is in operation, and wherein the plurality of memory cell structures are non-operational when the chip is in operation.

Aspect 21: A method for improved wafer assessment testing during fabrication, the method comprising: performing a memory wafer assessment test using memory cell array micro-structures on scribe lines of a memory wafer; verifying the memory wafer using results of the memory wafer assessment test; and performing wafer-to-wafer bonding of the memory wafer, if verified, and other verified memory wafers to form a memory wafer stack.

Aspect 22: The method of aspect 1, in which the performing comprises performing a memory cell array functional test for a memory wafer yield evaluation and a memory wafer rejection.

Aspect 23: The method of any of aspects 1 or 2, in which the performing comprises selecting the memory cell micro-structure corresponding to variable cell array sizes to perform a memory wafer yield evaluation and a memory wafer rejection.

Aspect 24: The method of any of aspects 1-3, further comprising stacking the memory wafer stack on a system-on-chip (SoC) wafer.

Aspect 25: The method of aspect 4, further comprising performing additional memory testing of the memory wafer stack through the SoC wafer.

Aspect 26: The method of aspect 5, further comprising forming a three-dimensional (3D) stacked memory package from the memory wafer stack on the SoC wafer.

Aspect 27: The method of any of aspects 1-6, in which the memory wafer comprises a plurality of dynamic random-access memory (DRAM) dies.

Aspect 28: The method of any of aspects 1-7, in which the memory wafer comprises the memory cell array micro-structures along horizontal scribe lines of the memory wafer.

Aspect 29: The method of any of aspects 1-8, in which the memory wafer comprises the memory cell array micro-structures along vertical scribe lines of the memory wafer.

Aspect 30: The method of any of aspects 1-9, in which the memory wafer comprises the memory cell array micro-structures along vertical scribe lines and horizontal scribe lines of the memory wafer.

Aspect 31: A memory wafer, comprising: a plurality of memory dies on the memory wafer; and a plurality of memory cell array micro-structures along scribe lines of the memory wafer.

Aspect 32: The memory wafer of aspect 11, in which the plurality of memory cell array micro-structures are arranged to perform a memory cell array functional test for a memory wafer yield evaluation and a memory wafer rejection of the plurality of memory dies.

Aspect 33: The memory wafer of any of aspects 11 or 12, in which the plurality of memory cell array micro-structures are configured according to variable cell array sizes to perform a memory wafer yield evaluation and a memory wafer rejection.

Aspect 34: The memory wafer of any of aspects 11-13, in which the memory wafer comprises a plurality of dynamic random-access memory (DRAM) dies.

Aspect 35: The memory wafer of any of aspects 11-14, in which the plurality of memory cell array micro-structures are arranged along horizontal scribe lines of the memory wafer.

Aspect 36: The memory wafer of any of aspects 11-15, in which the plurality of memory cell array micro-structures are arranged along vertical scribe lines of the memory wafer.

Aspect 37: The memory wafer of any of aspects 11-16, in which the plurality of memory cell array micro-structures are arranged along vertical scribe lines and horizontal scribe lines of the memory wafer.

Aspect 38: The memory wafer of any of aspects 11-17, in which the plurality of memory cell array micro-structures comprise a data pin, power pins, a clock pin, an address pin, and a command pin.

Aspect 39: The memory wafer of aspect 18, in which the plurality of memory cell array micro-structures are configured to compress data test values output through the data pin.

Aspect 40: The memory wafer of aspect 19, in which the plurality of memory cell array micro-structures are configured to compress data test values out through the data pin according to a Boolean method.

Aspect 41: The device of aspects 1 through 15, wherein the device is from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a substrate; and
a stack of chips coupled to the substrate, wherein the stack of chips comprises:
a logic chip; and
a first memory chip coupled to the logic chip, wherein the first memory chip comprises:
a first die substrate;
a first plurality of memory cells; and
a first plurality of memory cell structures located along at least one edge of the first memory chip.

2. The device of claim 1, wherein the first plurality of memory cell structures comprises:
a first memory cell structure comprising a first memory capacity; and
a second memory cell structure comprising a second memory capacity that is different from the first memory capacity.

3. The device of claim 2, wherein the first memory cell structure and the second memory cell structure are located along a first edge of the first memory chip.

4. The device of claim 2,
wherein the first memory cell structure is located along a first edge of the first memory chip, and
wherein the second memory cell structure is located along a second edge of the first memory chip.

5. The device of claim 2, wherein the first memory cell structure is a partial memory cell structure.

6. The device of claim 1, wherein the first plurality of memory cell structures is free of any electrical coupling with the first plurality of memory cells.

7. The device of claim 1, wherein the first plurality of memory cell structures comprises:
a plurality of logical cells configured as memory; and
a plurality of capacitors coupled to the plurality of logical cells.

8. The device of claim 1,
wherein the first memory chip is a dynamic random access memory (DRAM) chip,
wherein the first plurality of memory cells include operational logic cells when the chip is in operation, and
wherein the first plurality of memory cell structures are non-operational when the chip is in operation.

9. The device of claim 1,
wherein the stack of chips further comprises a second memory chip coupled to the first memory chip, and
wherein the second memory chip comprises:
a second die substrate;
a second plurality of memory cells; and
a second plurality of memory cell structures located along at least one edge of the second memory chip.

10. The device of claim 1, further comprising a first chip coupled to the substrate, wherein the first chip is located adjacent to the stack of chips.

11. The device of claim 10,
wherein the logic chip is a first chiplet based on a first technology node, and
wherein the first chip is a second chiplet based on a second technology node, that is different from the first technology node.

12. The device of claim 1,
wherein the logic chip is a first chiplet based on a first technology node, and
wherein the first memory chip is a second chiplet based on a second technology node, that is different from the first technology node.

13. The device of claim 12,
wherein the first technology node specifies a first minimum dimension for transistor sizes for the first chiplet,
wherein the second technology node specifies a second minimum dimension for transistor sizes for the second chiplet, and
wherein the second minimum dimension is different than the first minimum dimension.

14. The device of claim 10,
wherein the stack of chips is a high bandwidth memory (HBM), and wherein the first chip is implemented as a System on Chip (SoC).

15. A chip comprising:
a die substrate;
a plurality of memory cells; and
a plurality of memory cell structures located along at least one edge of the chip.

16. The chip of claim 15, wherein the plurality of memory cell structures comprises:
a first memory cell structure comprising a first memory capacity; and
a second memory cell structure comprising a second memory capacity that is different from the first memory capacity.

17. The chip of claim 16, wherein the first memory cell structure and the second memory cell structure are located along a first edge of the chip.

18. The chip of claim 16, wherein the first memory cell structure is a partial memory cell structure.

19. The chip of claim 15, wherein the plurality of memory cell structures is free of any electrical coupling with the plurality of memory cells.

20. The chip of claim 15,
wherein the chip is a dynamic random access memory (DRAM) chip,
wherein the plurality of memory cells include operational logic cells when the chip is in operation, and
wherein the plurality of memory cell structures are non-operational when the chip is in operation.
